(19) United States
(12) Patent Application Publication
(10) Pub. No.: US 2025/0006689 A1
(43) Pub. Date: Jan. 2, 2025

(54) STRUCTURES AND METHODS FOR BONDING DIES

(71) Applicant: ADEIA SEMICONDUCTOR BONDING TECHNOLOGIES INC., San Jose, CA (US)

(72) Inventors: Cyprian Emeka Uzoh, San Jose, CA (US); Gaius Gillman Fountain, JR., Youngsville, NC (US); Thomas Workman, San Jose, CA (US); Guilian Gao, Campbell, CA (US); Laura Wills Mirkarimi, Sunol, CA (US)

(21) Appl. No.: 18/513,145

(22) Filed: Nov. 17, 2023

Related U.S. Application Data
(60) Provisional application No. 63/511,422, filed on Jun. 30, 2023.

(51) Int. Cl. H01L 23/00; H01L 21/683; H01L 21/768; H01L 25/065

(52) U.S. Cl. CPC H01L 24/80; H01L 21/6835; H01L 21/76898; H01L 24/97; H01L 25/0652; H01L 2224/80895; H01L 2224/80896; H01L 2224/97; H01L 2924/01029; H01L 2924/014

(57) ABSTRACT

Disclosed is a bonded structure including a substrate that includes a surface and at least one bumper extending above the surface by a bumper height. The bonded structure further includes at least one die directly bonded to the surface adjacent the bumper.

### REFERENCE TO RELATED APPLICATIONS AND INCORPORATION BY REFERENCE

This application claims priority to U.S. provisional patent application No. 63/511,422, filed on Jun. 30, 2023, the disclosure of which is incorporated by reference herein in its entirety.

### BACKGROUND

### Field

The field relates to methods and structures for bonding dies, such as semiconductor and other microelectronic dies.

### Description of the Related Art

Microelectronic bonded structures can be assembled for packaging by bonding a plurality (a few, tens, hundreds, or more) of dies onto a host substrate (e.g., a larger die, a wafer, an interposer, etc.). Direct bonding generally, and hybrid bonding more specifically, can advantageously provide robust connections among the elements being bonded, and facilitate greater density of connections. However, manufacturing yield remains an issue for bonding microelectronic elements.

### BRIEF DESCRIPTION OF THE DRAWINGS

The detailed description is set forth with reference to the accompanying figures. The use of the same reference numbers in different figures indicates similar or identical items. Additionally, the use of reference numerals that increment by 100 with each figure (e.g., 310 in FIG. 3B, 410 in FIG. 4B, etc.) also indicate similar or identical items, unless otherwise specified.

For this discussion, the devices and systems illustrated in the figures are shown as having a multiplicity of components. Various implementations of devices and/or systems, as described herein, may include fewer components and remain within the scope of the disclosure. Alternatively, other implementations of devices and/or systems may include additional components, or various combinations of the described components, and remain within the scope of the disclosure.

These aspects and others will be apparent from the following description of preferred embodiments and the accompanying drawings, which are meant to illustrate and not to limit the invention, wherein:

FIG. 1A is a schematic side sectional view of two elements before being directly bonded, according to an embodiment.

FIG. 1B is a schematic side sectional view of the two elements of FIG. 1A after being directly bonded, according to an embodiment.

FIG. 2A is a schematic plan view of a bonded structure, showing the consequences of a misaligned die.

FIG. 2B is a schematic side sectional view of the bonded structure of FIG. 2A.

FIG. 3A is a schematic plan view of a bonded structure in which each die is separated from neighboring dies by a bumper, according to an embodiment.

FIG. 3B is a schematic side sectional view of the bonded structure of FIG. 3A.

FIG. 4A is a schematic plan view of a bonded structure in which multiple bonding regions each have a plurality of dies bonded thereto, and in which each die is separated from neighboring dies by a continuous bumper, according to an embodiment.

FIG. 4B is a schematic side sectional view of the bonded structure of FIG. 4A.

FIG. 5A is a schematic plan view of a bonded structure in which multiple bonding regions each have a plurality of dies bonded thereto, and in which each bonding region is separated from neighboring bonding regions by a bumper, according to an embodiment.

FIG. 5B is a schematic side sectional view of the bonded structure of FIG. 5A.

FIG. 5C is a schematic plan view of a bonded structure in which multiple bonding regions each have a plurality of dies bonded thereto, and in which each bonding region is separated from neighboring bonding regions by a bumper, according to an embodiment.

FIG. 5D is a schematic side sectional view of the bonded structure of FIG. 5C.

FIGS. 6A-6H present schematic plan views of various bonded structures with various geometries of dies, bumpers, and bumper elements, according to various embodiments.

FIG. 7 is a flow chart illustrating a method of forming a bonded structure. according to an embodiment.

FIGS. 8A-8K present a series of schematic side sectional views that show a method by which a bonded structure can be formed to have bumpers that comprise the same material as a substrate and is monolithic with the substrate, according to an embodiment.

FIGS. 9A-9I present a series of schematic side sectional views that show a method by which a bonded structure can be formed to have bumpers that comprise conductive material, according to an embodiment.

FIGS. 10A-10C present various schematic side sectional views of a bonded structure that can be formed by the method shown in FIGS. 9A-9I, wherein the bumper comprising conductive material is electrically connected to a commonly packaged external circuit, according to an embodiment.

FIGS. 11A-11H present a series of schematic side sectional views that show a method by which a bonded structure can be formed to have bumpers that are formed on a substrate, according to an embodiment.

FIGS. 12A-12G present a series of schematic side sectional views that show a method by which a bonded structure can be formed to have bumpers that are removable, according to an embodiment.

FIGS. 13A-13F present a series of schematic side sectional views that show a method by which a bonded structure that can be formed by a method similar to that shown in FIGS. 12A-12E can be further processed to have multiple pluralities of dies disposed onto a substrate, wherein one plurality of bonded dies can act as bumpers for the bonding of a subsequent plurality of dies, according to an embodiment.

FIG. 13G is a schematic plan view of a bonded structure similar to that shown in FIG. 13D, with multiple pluralities of dies disposed onto a substrate, wherein a first plurality of bonded dies alternate with a second plurality of dies in two dimensions. [0027]

FIGS. 14A-14E present a series of schematic side sectional views that show a method by which a bonded structure can be formed to have bumpers that comprise the same material as a substrate and is monolithic with the substrate, wherein the bumpers are also employed to mount dies thereon, according to an embodiment.

FIGS. 15A-15B present a sequence of schematic side sectional views that show a method by which a bonded structure can be formed to have bumpers tall enough to separate dies of multiple layers of die stacks, according to an embodiment.

### DETAILED DESCRIPTION

During direct or hybrid bonding operations, a die is attached to a predetermined or intended region on the surface of a prepared host or substrate. Occasionally, the attached dies may drift away from their predetermined region or site and come to rest at a location different from the intended region on the surface of the prepared substrate; thus, forming a misaligned die (e.g. a misplaced die or blocking die) on the substrate. It will be understood that when a die is described herein as being “misaligned” or “misplaced,” those descriptors refer only to the fact that the final position of the die is different than its predetermined or intended region. Such a die can end up in a location different from its predetermined or intended region in any number of ways, including but not limited to situations in which the die is originally placed incorrectly (e.g., by a pick-and-place apparatus) due to errors in picking up the die or errors in placing the die, situations in which the die is originally placed correctly (e.g., by a pick-and-place apparatus) but drifts to a different location before coming to rest, combinations of the above, or any other situation in which the die comes to rest at a location different from its correct location. Any such die can be referred to interchangeably herein as being “misaligned” or “misplaced,” without implying any particular process by which the die reaches the incorrect location. When a die is misplaced on a substrate, the misplaced die can interfere with (e.g., block) the placement and function of neighboring dies. A misplaced or misaligned die that interferes with or blocks the placement and/or function of neighboring dies can be referred to as a “blocking die.” In this way, one misplacement can cause undesirable yield loss amongst others. Preventing a misplaced die on a substrate from interfering with the placement of neighboring dies, e.g., isolating misplaced dies, can improve manufacturing yield. This problem is particularly acute for direct bonding, where dielectric materials sufficiently prepared (e.g., sufficiently planarized) for direct bonding can begin to bond to a host element (e.g., die, wafer, interposer, dielectric surface, flat panel surface) once placed in contact with the host element at room temperature, even before any further processing.

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one clement and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 108a and/or 108b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two clements. The resulting bond often evinces sharp interfaces with conductors from both elements, and is subject to reversal by reheating. By way of contrast, direct metal bonding as employed in hybrid bonding does not require melting or an intermediate fusible metal alloy. and can result in strong mechanical and electrical connections, often demonstrating interdiffusion of the bonded conductive features with grain growth across the bonding interface between the elements, even without the much higher temperatures and pressures of thermocompression bonding.

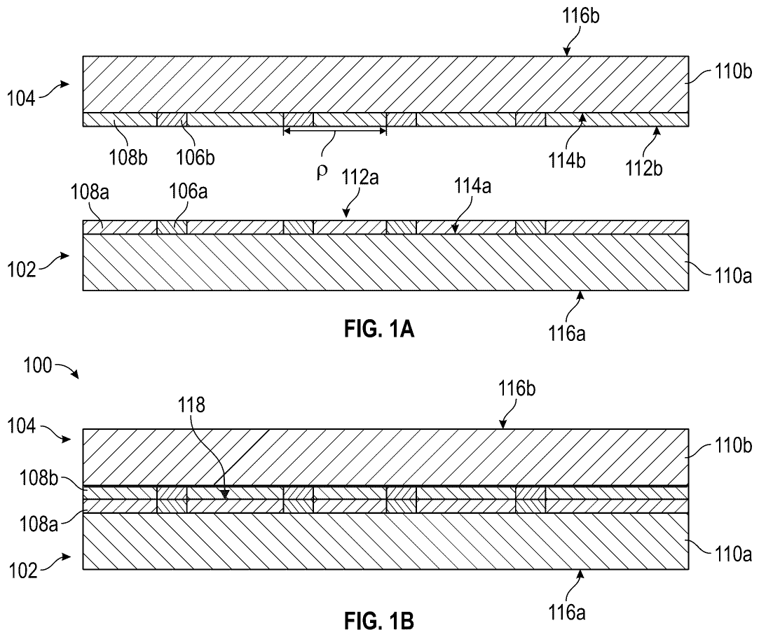

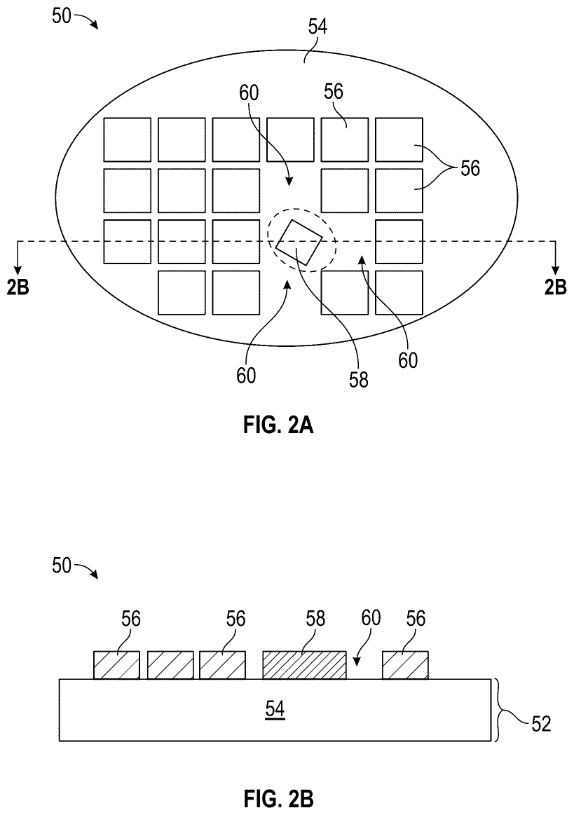

FIGS. 1A and 1B schematically illustrate cross-sectional side views of first and second elements 102, 104 prior to and after, respectively, a process for forming a directly bonded structure, and more particularly a hybrid bonded structure, according to some embodiments. In FIG. 1B, a bonded structure 100 comprises the first and second elements 102 and 104 that are directly bonded to one another at a bond interface 118 without an intervening adhesive. Conductive features 106a of a first element 102 may be electrically connected to corresponding conductive features 106b of a second element 104. In the illustrated hybrid bonded structure 100, the conductive features 106a are directly bonded to the corresponding conductive features 106b without intervening solder or conductive adhesive.

The conductive features 106a and 106b of the illustrated embodiment are embedded in, and can be considered part of, a first bonding layer 108a of the first element 102 and a second bonding layer 108b of the second element 104, respectively. Field regions of the bonding layers 108a, 108b extend between and partially or fully surround the conductive features 106a, 106b. The bonding layers 108a, 108b can comprise layers of non-conductive materials suitable for direct bonding, as described above, and the field regions are directly bonded to one another without an adhesive. The non-conductive bonding layers 108a, 108b can be disposed on respective front sides 114a, 114b of base substrate portions 110a, 110b.

The first and second elements 102, 104 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 102, 104, and back-end-of-line (BEOL) interconnect layers over such semiconductor portions. The bonding layers 108a, 108b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 110a, 110b, and can electrically communicate with at least some of the conductive features 106a, 106b. Active devices and/or circuitry can be disposed at or near the front sides 114a, 114b of the base substrate portions 110a, 110b, and/or at or near opposite backsides 116a, 116b of the base substrate portions 110a, 110b. In other embodiments, the base substrate portions 110a, 110b may not include active circuitry, but may instead comprise dummy substrates, passive interposers, passive optical elements (e.g., glass substrates, gratings, lenses), etc. The bonding layers 108a, 108b are shown as being provided on the front sides of the elements, but similar bonding layers can be additionally or alternatively provided on the back sides of the elements.

In some embodiments, the base substrate portions 110a, 110b can have significantly different coefficients of thermal expansion (CTEs), and bonding elements that include such different based substrate portions can form a heterogenous bonded structure. The CTE difference between the base substrate portions 110a and 110b, and particularly between bulk semiconductor (typically single crystal) portions of the base substrate portions 110a, 110b, can be greater than 5 ppm/° C. or greater than 10 ppm/° C. For example, the CTE difference between the base substrate portions 110a and 110b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 110a, 110b can comprise optoelectronic single crystal materials, including perovskite materials, that are useful for optical piezoelectric or pyroelectric applications, and the other of the base substrate portions 110a, 110b comprises a more conventional substrate material. For example, one of the base substrate portions 110a, 110b comprises lithium tantalate (LiTaO₃) or lithium niobate (LiNbO₃), and the other one of the base substrate portions 110a, 110b comprises silicon (Si), quartz, fused silica glass, sapphire, or a glass. In other embodiments, one of the base substrate portions 110a, 110b comprises a III-V single semiconductor material, such as gallium arsenide (GaAs) or gallium nitride (GaN), and the other one of the base substrate portions 110a, 110b can comprise a non-III-V semiconductor material, such as silicon (Si), or can comprise other materials with similar CTE, such as quartz, fused silica glass, sapphire, or a glass. In still other embodiments, one of the base substrate portions 110a, 110b comprises a semiconductor material and the other of the base substrate portions 110a, 110b comprises a packaging material, such as a glass, organic or ceramic substrate.

In some arrangements, the first element 102 can comprise a singulated element, such as a singulated integrated device die. In other arrangements, the first element 102 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 104 can comprise a singulated element, such as a singulated integrated device die. In other arrangements, the second element 104 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 102, 104 are shown, any suitable number of elements can be stacked in the bonded structure 100. For example, a third element (not shown) can be stacked on the second element 104, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 102. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 108a, 108b, the bonding layers 108a, 108b can be prepared for direct bonding. Non-conductive bonding surfaces 112a, 112b at the upper or exterior surfaces of the bonding layers 108a, 108b can be prepared for direct bonding by polishing, for example, by chemical mechanical polishing (CMP). The roughness of the polished bonding surfaces 112a, 112b can be less than 30 Å rms. For example, the roughness of the bonding surfaces 112a and 112b can be in a range of about 0.1 Å rms to 15 Å rms, 0.5 Å rms to 10 Å rms, or 1 Å rms to 5 Å rms. Polishing can also be tuned to leave the conductive features 106a, 106b recessed relative to the field regions of the bonding layers 108a, 108b.

Preparation for direct bonding can also include cleaning and exposing one or both of the bonding surfaces 112a, 112b to a plasma and/or etchants to activate at least one of the surfaces 112a, 112b. In some embodiments, one or both of the surfaces 112a, 112b can be terminated with a species after activation or during activation (e.g., during the plasma and/or etch processes). Without being limited by theory, in some embodiments, the activation process can be performed to break chemical bonds at the bonding surface(s) 112a, 112b, and the termination process can provide additional chemical species at the bonding surface(s) 112a, 112b that alters the chemical bond and/or improves the bonding energy during direct bonding. In some embodiments, the activation and termination are provided in the same step, e.g., a plasma to activate and terminate the surface(s) 112a, 112b. In other embodiments, one or both of the bonding surfaces 112a, 112b can be terminated in a separate treatment to provide the additional species for direct bonding. In various embodiments, the terminating species can comprise nitrogen. For example, in some embodiments, the bonding surface(s) 112a, 112b can be exposed to a nitrogen-containing plasma. Other terminating species can be suitable for improving bonding energy, depending upon the materials of the bonding surfaces 112a, 112b. Further, in some embodiments, the bonding surface(s) 112a, 112b can be exposed to fluorine. For example, there may be one or multiple fluorine concentration peaks at or near a bond interface 118 between the first and second elements 102, 104. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47. 52-55, and 60-64; Col. 12, lines 3-14, 31-33, and 55-67; Col. 14, lines 38-40 and 44-50; and 10,434,749 at Col. 4, lines 41-50; Col. 5, lines 7-22, 39, 55-61; Col. 8, lines 25-31. 35-40, and 49-56; and Col. 12, lines 46-61, the activation and termination teachings of which are incorporated by reference herein.

Thus, in the directly bonded structure 100, the bond interface 118 between two non-conductive materials (e.g., the bonding layers 108a, 108b) can comprise a very smooth interface with higher nitrogen (or other terminating species) content and/or fluorine concentration peaks at the bond interface 118. In some embodiments, the nitrogen and/or fluorine concentration peaks may be detected using various types of inspection techniques, such as SIMS techniques. The polished bonding surfaces 112a and 112b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 108a and 108b can be directly bonded to one another without an adhesive. In some embodiments, the elements 102, 104 are brought together at room temperature, without the need for application of a voltage, and without the need for application of external pressure or force beyond that used to initiate contact between the two elements 102, 104. Contact alone can cause direct bonding between the non-conductive surfaces of the bonding layers 108a, 108b (e.g., covalent dielectric bonding). Subsequent annealing of the bonded structure 100 can cause the conductive features 106a, 106b to directly bond.

In some embodiments, prior to direct bonding, the conductive features 106a, 106b are recessed relative to the surrounding field regions, such that a total gap between opposing contacts after dielectric bonding and prior to anneal is less than 15 nm, or less than 10 nm. Because the recess depths for the conductive features 106a and 106b can vary across each element, due to process variation, the noted gap can represent a maximum or an average gap between corresponding conductive features 106a, 106b of two joined elements (prior to anneal). Upon annealing, the conductive features 106a and 106b can expand and contact one another to form a metal-to-metal direct bond.

During annealing, the conductive features 106a, 106b (e.g., metallic material) can expand while the direct bonds between surrounding non-conductive materials of the bonding layers 108a, 108b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature, such that bonds can form with lower anneal temperatures compared to soldering or thermocompression bonding.

In various embodiments, the conductive features 106a, 106b can comprise discrete pads, contacts, electrodes, or traces at least partially embedded in the non-conductive field regions of the bonding layers 108a, 108b. In some embodiments, the conductive features 106a, 106b can comprise exposed contact surfaces of TSVs (e.g., through silicon vias).

As noted above, in some embodiments, in the elements 102, 104 of FIG. 1A prior to direct bonding, portions of the respective conductive features 106a and 106b can be recessed below the non-conductive bonding surfaces 112a and 112b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 106a, 106b or to average depths of the recesses relative to local non-conductive field regions. Even for an individual conductive feature 106a, 106b, the vertical recess can vary across the feature, and so can be measured at or near the lateral middle or center of the cavity in which a given conductive feature 106a, 106b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 106a, 106b across the direct bond interface 118 (e.g., small or fine pitches for regular arrays).

In some embodiments, a pitch p of the conductive features 106a, 106b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 106a and 106b to one of the lateral dimensions (e.g., a diameter) of the bonding pad is less than is less than 20, or less than 10, or less than 5, or less than 3 and sometimes desirably less than 2. In various embodiments, the conductive features 106a and 106b and/or traces can comprise copper or copper alloys, although other metals may be suitable, such as nickel, aluminum, or alloys thereof. The conductive features disclosed herein, such as the conductive features 106a and 106b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 102, 104, as shown, the orientations of one or more conductive features 106a, 106b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 106b in the bonding layer 108b (and/or at least one internal conductive feature, such as a BEOL feature) of the upper clement 104 may be tapered or narrowed upwardly, away from the bonding surface 112b. By way of contrast, at least one conductive feature 106a in the bonding layer 108a (and/or at least one internal conductive feature, such as a BEOL feature) of the lower element 102 may be tapered or narrowed downwardly, away from the bonding surface 112a. Similarly, any bonding layers (not shown) on the backsides 116a, 116b of the elements 102, 104 may taper or narrow away from the backsides, with an opposite taper orientation relative to front side conductive features 106a, 106b of the same element.

As described above, in an anneal phase of hybrid bonding, the conductive features 106a, 106b can expand and contact one another to form a metal-to-metal direct bond. In some embodiments, the materials of the conductive features 106a, 106b of opposite elements 102, 104 can interdiffuse during the annealing process. In some embodiments, metal grains grow into each other across the bond interface 118. In some embodiments, the metal is or includes copper, which can have grains oriented along the 111 crystal plane for improved copper diffusion across the bond interface 118. In some embodiments, the conductive features 106a and 106b may include nanotwinned copper grain structure, which can aid in merging the conductive features during anneal. There is substantially no gap between the non-conductive bonding layers 108a and 108b at or near the bonded conductive features 106a and 106b. In some embodiments, a barrier layer may be provided under and/or laterally surrounding the conductive features 106a and 106b (e.g., which may include copper). In other embodiments, however, there may be no barrier layer under the conductive features 106a and 106b.

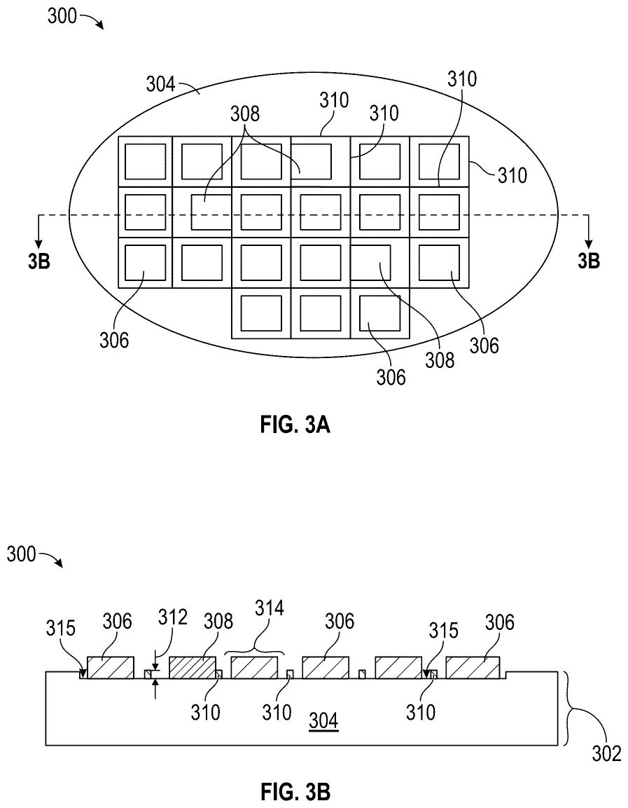

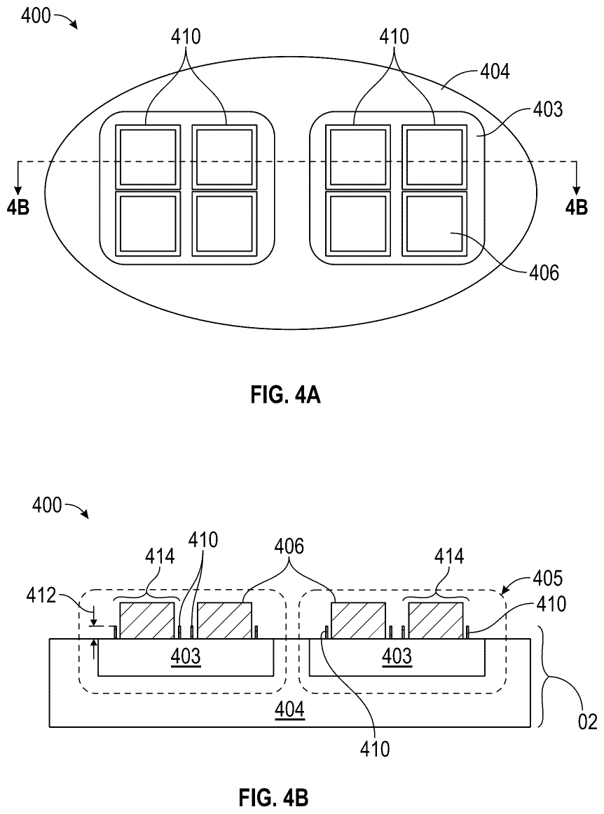

FIGS. 2A-2B depict a bonded structure 50 comprising a microelectronic structure 52, including a substrate 54, and a plurality of dies (e.g., 56) disposed (e.g., bonded) thereon. Each die 56 can represent a microelectronic structure or device that has been singulated or “diced” from a larger substrate, panel or web of manufactured devices. For example, each die can represent an individual active or passive device or a circuit of multiple connected devices, such as a capacitor, inductor, resistor, transistor, MEMS device, integrated circuit, optical elements, etc. The substrate 54 can represent, for example, a wafer or flat panel having a plurality of similar such devices (e.g., integrated circuits) formed therein, prior to singulation. FIG. 2A depicts an overhead plan view of the bonded structure 50, and FIG. 2B depicts a side sectional view of the bonded structure 50 shown in FIG. 2A, along lines 2B-2B. FIGS. 2A and 2B depict a misaligned die 58 that can block dies in adjacent locations. The substrate 54 has an array of die regions, where dies 56 are intended to be placed. Many of the dies 56 are properly attached on their respective die regions, forming an array or grid. But the misaligned die 58 is depicted as rotated and/or translated and/or having otherwise drifted away from its intended position or die region in the array of the other dies 56. The misalignment of the misaligned die 58 can have any of a number of causes, such as slippage on a cushion of air during placement of the die, slippage during release of the die from the pick-and-place apparatus, other errors in pick up or placement of the die, etc. The misalignment of misaligned die 58 can cause the misaligned die 58 to block or otherwise interfere with the placement of neighboring dies. Such interference can cause neighboring predetermined die regions of the substrate to be, for example, skipped, as depicted as skipped die regions 60. A drifted die—as shown by the incorrect location of the misaligned die 58—can cause errors in the placement of other dies—as shown by skipped die regions 60, creating a zone or region of condemned predetermined sites or regions around misaligned die 58. The errors in the placement of die or dies in the skipped die regions 60 represent a reduction of manufacturing yield: in the schematic of FIG. 2A, one manufacturing error (the misaligned die 58) leads to a reduction of yield by four (one misaligned die 58 and three skipped die regions 60). Methods and structures described herein can limit the yield loss from the formation of blocking dies. In embodiments where multiple die stacking is contemplated, known good dies cannot be stacked over the misaligned die 58 nor over the condemned spaces around the misaligned die 58 (e.g., skipped die regions 60). The loss of die stacking on the misaligned die 58 and adjacent condemned predetermined sites or regions (e.g., skipped die regions 60) can further aggravate the yield losses on the substrate 54.

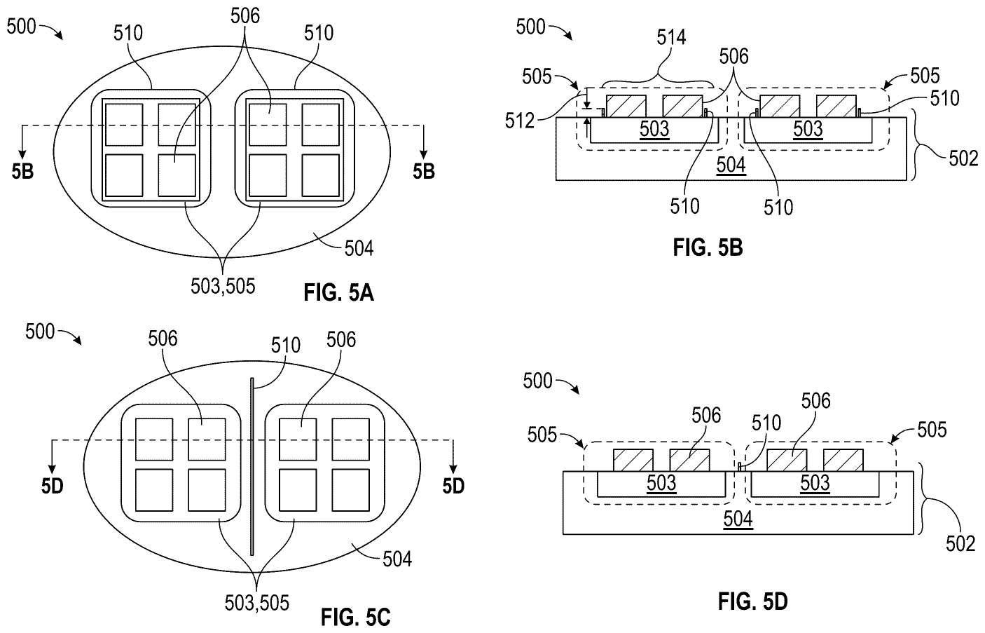

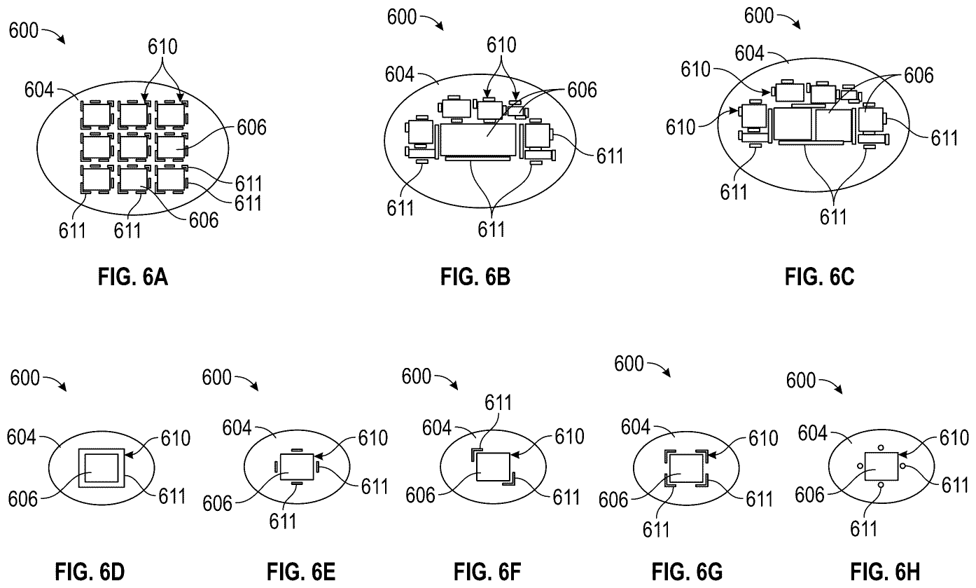

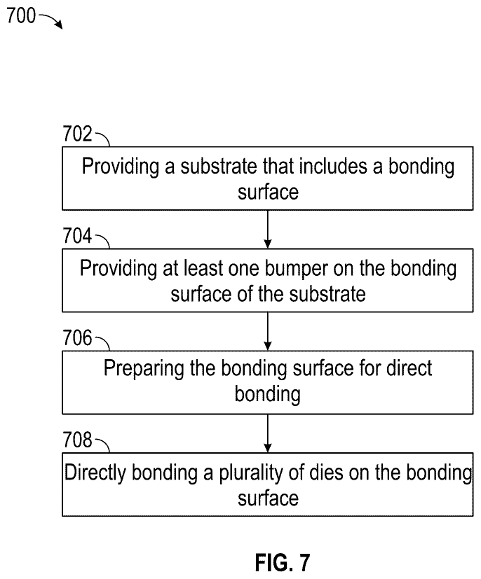

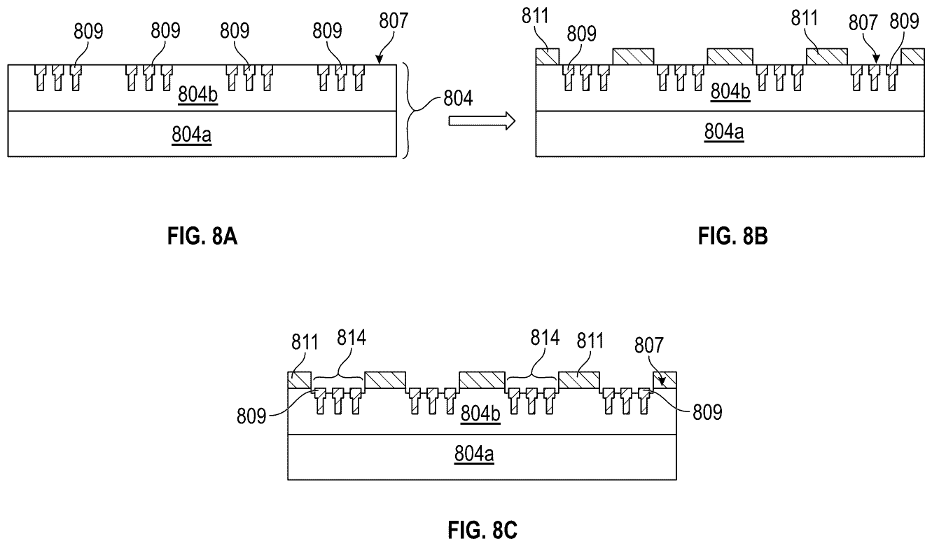

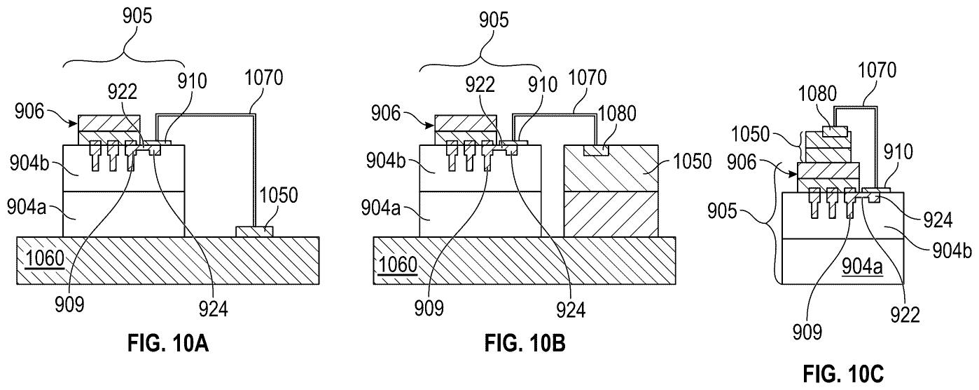

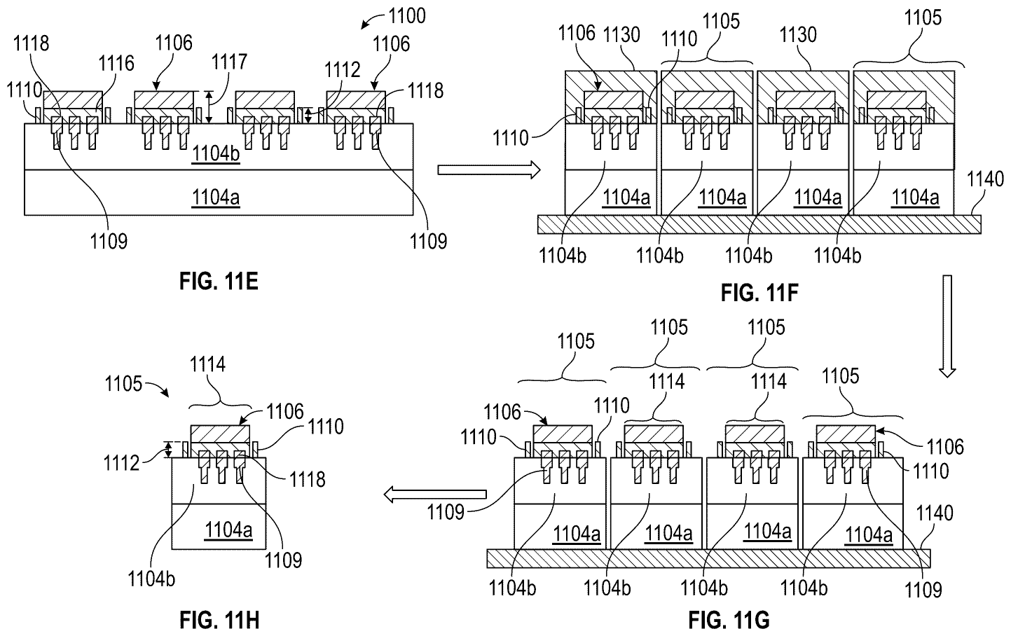

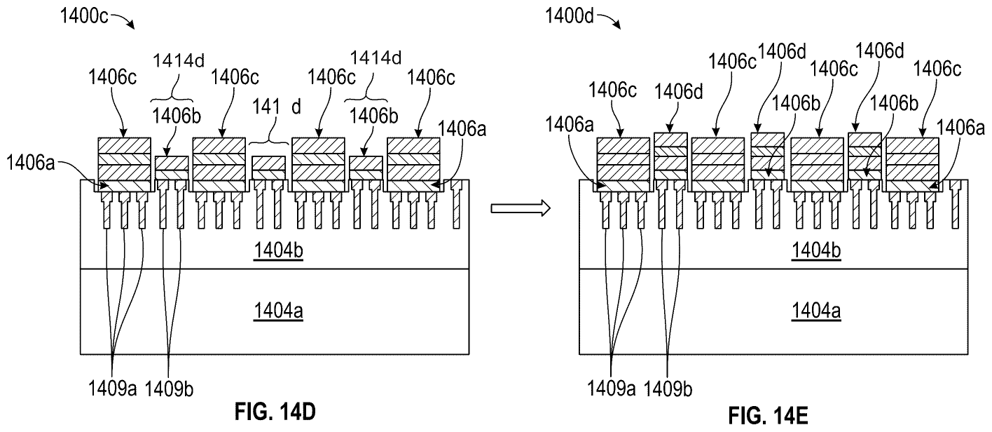

FIGS. 3A-3B depict a bonded structure 300 similar to the bonded structure 50 of FIGS. 2A-2B. Like FIGS. 2A-2B, FIGS. 3A-3B depict a bonded structure 300 comprising a microelectronic structure 302, including a substrate 304, with a plurality of dies (e.g., dies 306) disposed onto the bonding surfaces 315 of the substrate 304, in a similar array or grid configuration. FIG. 3A depicts an overhead plan view of the bonded structure 300, and FIG. 3B depicts a side sectional view of the bonded structure 300 shown in FIG. 3A along lines 3B-3B. FIGS. 3A-3B also depict misaligned dies 308. But in FIGS. 3A-3B, the microelectronic structure 302 further comprises bumpers 310 that extend above the bonding surfaces 315 of the substrate 304 by a bumper height 312. The space between bumpers 310 defines a die pocket 314. In some embodiments, the bumpers 310 can prevent misaligned dies 308 from interfering with the placement of neighboring dies (e.g., properly aligned dies 306) by constraining the misaligned dies 308 within their respective die pockets 314. In some embodiments, the bumpers 310 can effectively confine and isolate misaligned dies 308, preventing slipped dies from interfering with adjacent die locations, thus eliminating the formation of blocking dies or blocking dies phenomenon. This can increase manufacturing yield. Misaligned dies 308 are restricted within their die pockets 314 and gross misalignments of any die is constrained within die pocket 314, thus, reducing or eliminating dies drifting to adjacent die locations or sites. The bumpers 310 depicted in FIGS. 3A-3B can comprise the same material and be monolithic with the substrate 304 (as shown, for example, in FIGS. 8A-8K and 14A-14E). But, as explained herein (e.g., in FIGS. 4A-4B, 9A-9I, 11A-11H, 12A-12G, 13A-13F, and 15A-15B), the bumpers 310 need not be so limited. The bumpers 310 depicted in FIGS. 3A-3B are shown as continuous. But, as explained herein (e.g., in FIGS. 6A-6C and 6E-6H), the bumpers 310 need not be so limited.

Throughout this disclosure, unless otherwise specified, a bonded structure (e.g., 300, 400, 500, 800, 900, etc.) can comprise a microelectronic structure (e.g., 302, 402, 502, 802, 902, etc.) with dies (e.g., 306, 406, 506, 806, 906, etc.) disposed thereon. The microelectronic structure can comprise a substrate (e.g., 304, 404, 504, 804, 904, etc.) and bumpers (e.g., 310, 410, 510, 810, 910, etc.) extending above a bonding surface of the substrate. The substrate can include multiple elements integrated therein, to be singulated from one another. The substrate and the dies can each comprise any of a variety of microelectronic elements themselves, such as integrated circuits, passive devices, active devices (e.g., transistors), MEMS devices, etc. In some cases, the substrate and/or die can include dummy elements without electronic devices.

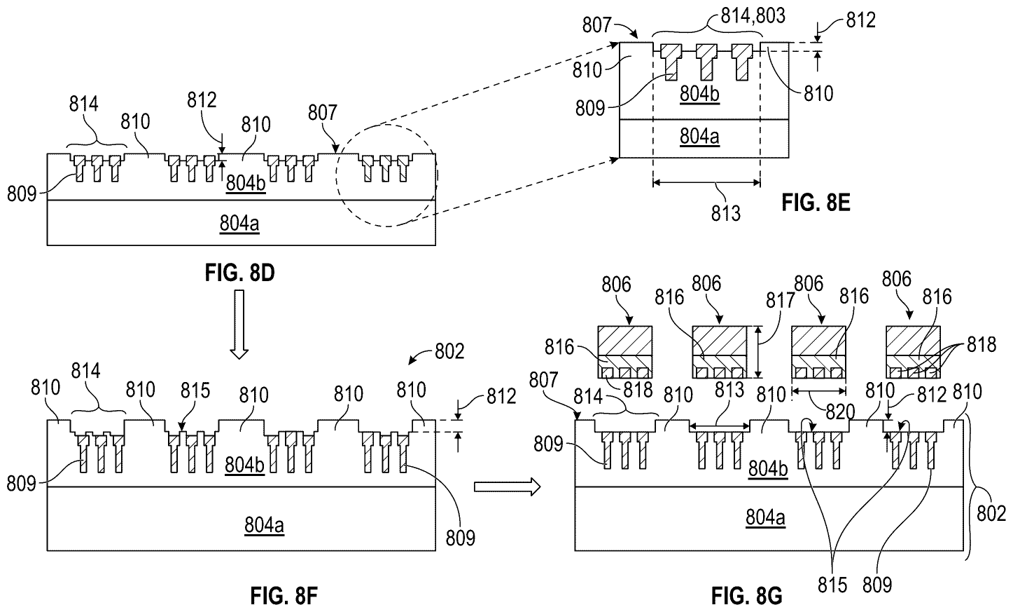

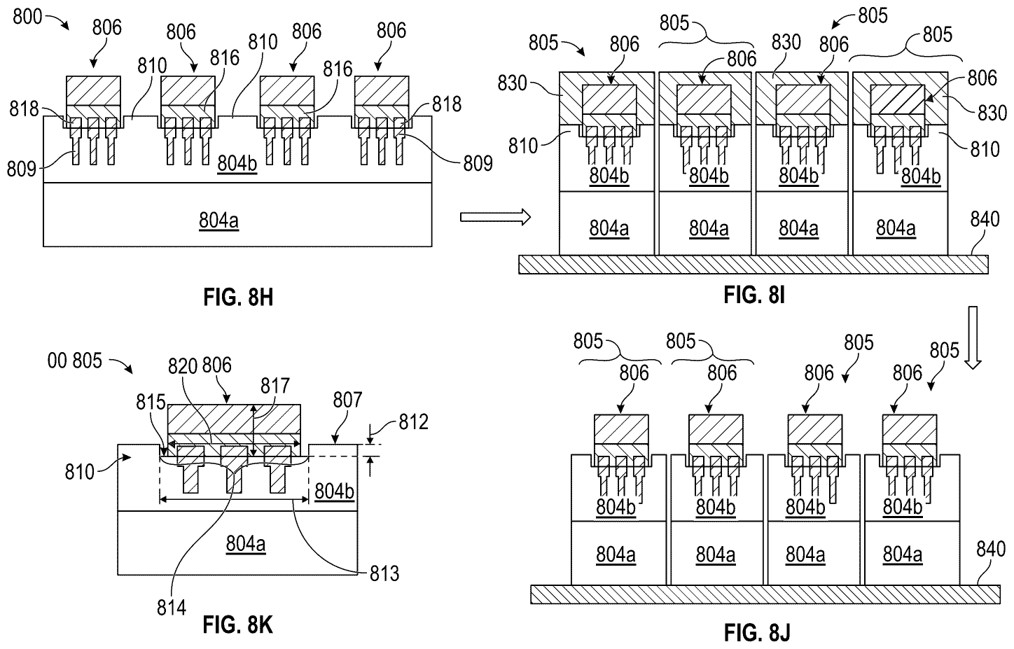

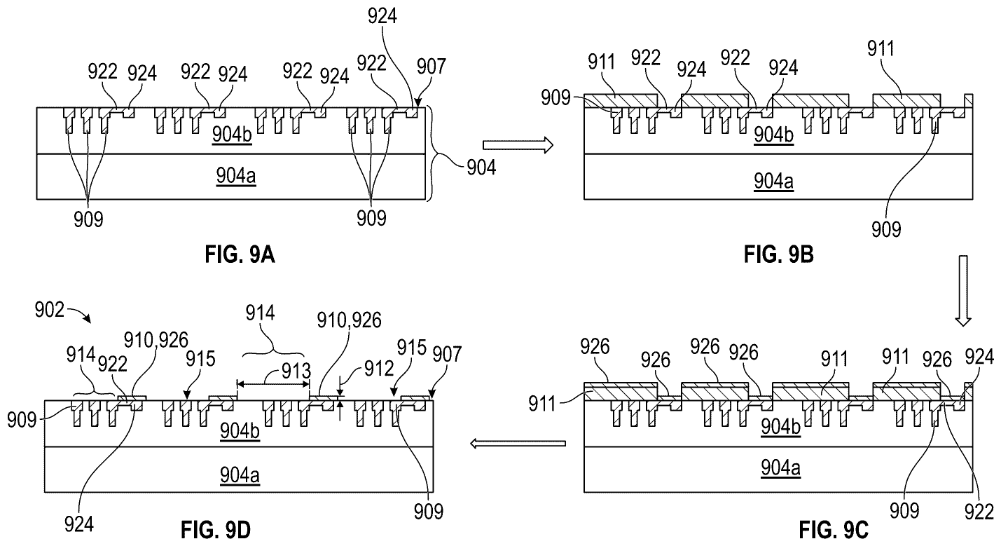

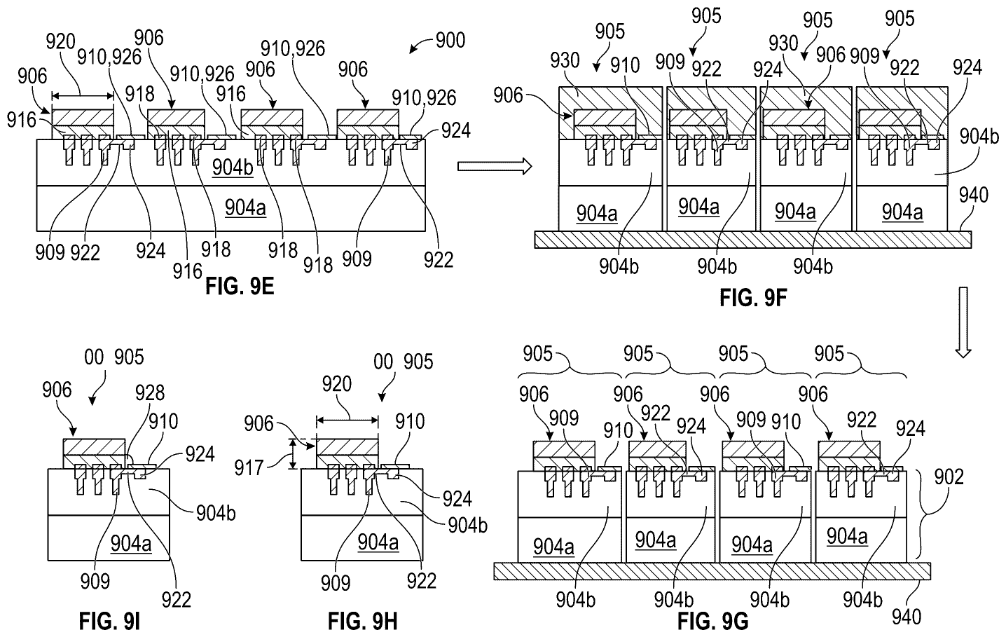

FIGS. 4A-4B and FIGS. 5A-5D show three similar configurations but with different bumper structures. FIG. 4A depicts a plan view of one configuration, of which FIG. 4B depicts a side sectional view along lines 4B-4B. FIG. 5A depicts a plan view of another configuration, of which FIG. 5B depicts a side sectional view along lines 5B-5B. And FIG. 5C depicts a plan view of another configuration, of which FIG. 5D depicts a side sectional view along lines 5D-5D. Each of the figures depict a bonded structure (e.g., 400 in FIGS. 4A-4B, and 500 in FIGS. 5A-5D). The bonded structure 400, 500 comprises a microelectronic structure 402, 502 with dies 406, 506 disposed thereon. Each microelectronic structure 402, 502 comprises a substrate 404, 504 and a plurality of bonding regions 403, 503. In some embodiments, each bonding region 403, 503 can correspond to a package 405, 505. In some embodiments, each package 405, 505 can correspond to a separate lower device after singulation. As such, in some embodiments, each package 405, 505 can function as a single unit. In some embodiments, if one die 406, 506 in one package 405, 505 is misaligned, that entire package 405, 505 might be compromised. Each microelectronic structure 402, 502 further comprises bumpers 410, 510 that extend above the bonding surface of the substrate 404, 504 by a bumper height 412, 512. In each of FIGS. 4A-4B and FIGS. 5A-5D, the bumpers 410, 510 separate neighboring bonding regions 403, 503 or packages 405, 505. The bumpers 410, 510 depicted in FIGS. 4A-5D can comprise a material different from a material of the substrate 404, 504 at the bonding surface. But, as explained herein (e.g., in FIGS. 3A-3B), the bumpers 410, 510 need not be so limited. The bumpers 410, 510 depicted in FIGS. 4A-5D are shown as continuous. But, as explained herein (e.g., in FIGS. 6A-6C and 6E-6H), the bumpers 410, 510 need not be so limited.

FIGS. 4A-4B and FIGS. 5A-5D differ primarily in the geometry of the bumpers 410, 510. In FIGS. 4A-4B, each die 406 is surrounded by its own bumper(s) 410, illustrated as a single continuous bumper. Disposed within each die pocket 414 is a single die 406. As shown in FIG. 4B, each die 406 is separated from its neighbors by two bumpers 410. But it will be understood that a die 406 can be separated from its neighbors by a different number of bumpers 410 (e.g., FIG. 3A-3B depict one bumper 310 separating dies 306). Such a geometry (e.g., one die pocket 414 per die 406) can be well suited for a situation in which each die is independent from one another, in which one incorrectly located die 406 may not compromise the integrity of the other dies 406 on the same bonding region 403 or the package 405 of which they are a part.

In FIGS. 5A-5B, each bonding region 503 is surrounded by its own bumper 510. Disposed within each die pocket 514 is all of the dies 506 of a single bonding region 503 or package 505. As shown in FIG. 5B, neighboring dies 506 that are disposed on the same bonding region 503 are not separated by a bumper 510, but the dies 506 of the neighboring bonding regions 503 are separated from one another by at least one bumper 510. and in the illustrated embodiment by two bumpers 510. But it will be understood that a die 506 can be separated from its neighbors by a different number of bumpers 510 (e.g., FIGS. 3A-3B depict one bumper 310 separating dies 306).

In FIGS. 5C-5D, each bonding region 503 is separated from neighboring bonding regions 503 by a bumper 510. The bumper 510 in FIG. 5C comprises a single continuous line. As shown in FIG. 5D, neighboring dies 506 that are disposed on the same bonding region 503 are not separated by a bumper 510, but the dies 506 of the neighboring bonding regions 503 are separated from one another by a bumper 510.

The bumper 510 geometries depicted in FIGS. 5A-5B (e.g., one die pocket 514 per bonding region 503) can be well suited for a situation in which each die 506 on a single bonding region 503 depends on the others: if one die 506 is misaligned, the integrity of that entire package 505 can be compromised. In such a situation, there may not be a need to separate each die 506, as separating the larger bonding regions 503 can suffice. The bumpers 510 still serve to prevent one die placement error or slippage from affecting the yield of neighboring packages 505.

In each of FIGS. 4A-4B and 5A-5D, the bonding regions 403, 503, which can represent lower devices or resultant packages 405, 505, are depicted as having a substantially similarly shaped and/or sized footprint on the substrate 404, 504 as any neighboring bonding regions 403, 503. However, the bonding regions (e.g., bonding regions 403, 503) need not be so limited. Indeed, bonding regions (e.g., bonding regions 403, 503) on a common substrate can have substantially differently shaped and/or sized footprints on the substrate. Bonding regions that have substantially differently shaped and/or sized footprints on the substrate can be differently patterned in the reticle or other lithographic features, rather than merely different due to minor processing variations.

FIGS. 6A-6H depict schematic plan views of various bonded structures 600 with various geometries of dies 606 and bumpers 610 disposed on a substrate 604. FIGS. 6A-6H are nonlimiting examples of geometries of the dies 606 and the bumpers 610, illustrating a variety of available geometries. FIG. 6A, for example, depicts various dies 606 with uniform or substantially uniform size and shape, and the dies 606 are arranged in a grid or array on the substrate 604. Each of a plurality of dies 606 is separated from its neighbors by at least one bumper 610, and in the illustrated embodiment the bumpers 610 each comprise a plurality of discontinuous bumper elements 611 that together surround die pockets. FIG. 6B, for example, depicts various dies 606 with varying sizes and shapes, and the dies 606 are arranged in a non-grid configuration on the substrate 604. As with FIG. 6A, each of a plurality of dies 606 in FIG. 6B is separated from its neighbors by at least one bumper 610. and in the illustrated embodiment each bumper 610 comprises a plurality of discontinuous bumper elements 611. And FIG. 6C, for example, depicts various dies 606 with varying sizes and shapes, and the dies 606 are arranged in a non-grid configuration on the substrate 604. In FIG. 6C, most but not all dies 606 are separated from their neighbors by at least one bumper 610. Also in FIG. 6C, the bumper elements 611 have different lengths.

FIGS. 6D-6H depict various geometries of bumpers 610 and bumper elements 611. Generally, bumpers (e.g., bumpers 610) are containment elements that reduce or eliminate the likelihood that a misplaced die will interfere with the placement or function of any neighboring dies. In this manner, in some embodiments, the bumpers (e.g., bumpers 610) can be dams or enclosures or pens or fences that constrain the movement of dies (e.g., dies 606). The bumpers 610 can comprise one or multiple bumper elements 611. Thus, where the bumper 610 comprises a single, continuous bumper elements 611, the bumper 610 and the bumper element 611 can be coextensive. The dies 606 in each of FIGS. 6D-6H are constrained on the substrate 604 by a single bumper 610, but each figure depicts a different geometry of the bumper elements 611. In FIG. 6D, the single bumper 610 comprises a single bumper element 611 that is continuous and surrounds the die 606. In such embodiments, the single bumper 610 acts like a dam or an enclosure. In FIG. 6E, the single bumper 610 comprises four discontinuous bumper elements 611 that are each individual line segments adjacent to but shorter than a corresponding edge of the die 606. In FIG. 6F, the single bumper 610 comprises two discontinuous bumper elements 611 that each include two segments at 90° to one another and frame opposite corners of the die 606. In FIG. 6G, the single bumper 610 comprises four discontinuous bumper elements 611 that each include two segments at 90° to one another and frame a corner of the die 606. And in FIG. 6H, the single bumper 610 comprises four discontinuous bumper elements 611 that are each beside a different edge of die 606, and each bumper element 611 has a circular or substantially circular cross-section, which gives the bumper elements 611 the appearance of four posts. FIGS. 6A-6H will be understood to be nonlimiting examples of particular geometries available for the dies 606, the bumpers 610, and the bumper elements 611, each of which can have their own advantages.

It will be understood that in each of FIGS. 2A-6H, the dies 56, 306, 406, 506, 606 can be directly bonded to the surface of the substrate 54, 304, 404, 504, 604. Moreover, it will be understood that throughout this disclosure, anytime an element (e.g., a die 306, 406, 506, 606, 806, 906, 1106, 1206, 1306a, 1306b, 1306c, 1306d, 1406a, 1406b, 1406c, 1406d, 1506a, 1506b) is disposed onto another element (e.g., a substrate 304, 404, 504, 604, 804, 904, 1104, 1204, 1304, 1404, 1504 or another die 1306a, 1306b, 1406a, 1406b, 1506a), it can be accomplished by hybrid bonding, without an intervening adhesive, as described herein. It will also be understood that throughout this disclosure—whether expressly stated or not—before an element is hybrid bonded to another element, one or both surfaces to be bonded can be planarized, activated and/or terminated for hybrid bonding, as described herein. Typically both surfaces to be bonded are provided with the desired planarity, while one or both surfaces are activated. The activation process may include exposing the smooth bonding surface to a plasma source, particularly oxygen or nitrogen plasma or combinations thereof. For example, such activation can include rinsing the activated surface with an alkaline solution or dilute acidic solution or deionized water (DI) or combinations thereof. After any wet processing step(s), the substrates of interest can be spun dry or dried by known methods. It will also be appreciated that, throughout this disclosure, after at least one element (e.g., die 806, 906, 1106, 1206, etc.) is hybrid bonded to another element (e.g., microelectronic structure 802, 902, 1102, 1202, etc. or another die 1306a, 1306b, 1406a, 1406b, 1506a), the bond can be strengthened. For example, covalent bonds can be formed between prepared dielectric surfaces simply by bringing the surfaces into contact at room temperature. Subsequent annealing of the bonded structure (e.g., 800, 900, 1100, 1200, etc.) can both expand and merge/bond aligned conductive features at the interface, and strengthen the covalent bonds formed between the bonded dielectric surfaces.

It will also be understood that throughout this disclosure, dies (e.g., 306, 406, 506, 606, 806, 906, etc.) can have backside conductive features (not shown), as well as through substrate vias (TSVs) connecting to the backside conductive features (not shown). These backside conductive features and TSVs can be in dies (e.g., 1306a, 1306b, 1406a, 1406b, and 1506a) that are meant to have additional dies (e.g., 1306c, 1306d, 1406c, 1406d, and 1506b) stacked thereover.

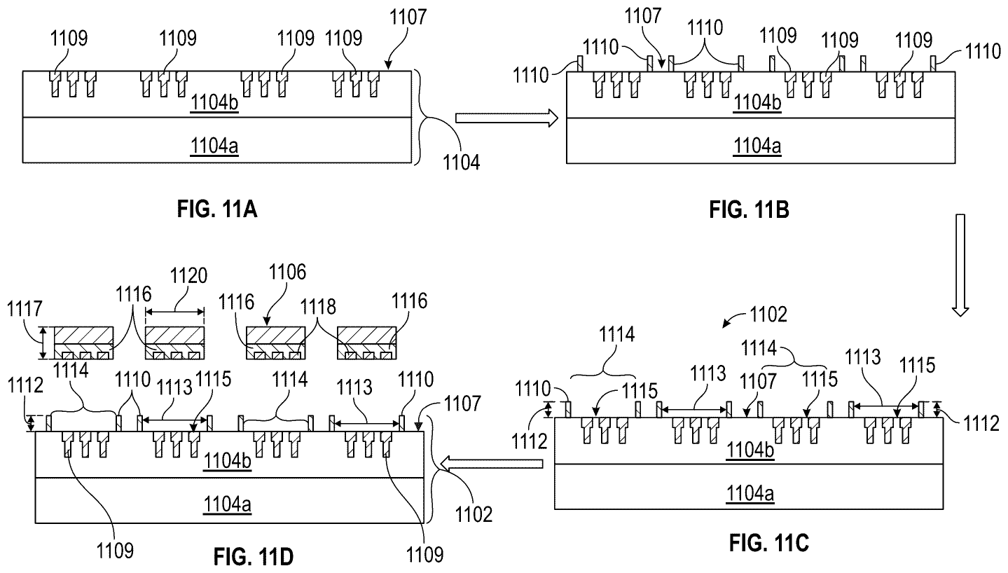

FIG. 7 depicts a simplified method 700 of some embodiments of forming a bonded structure, e.g., 300, 400, 500, 600. In block one 702, a substrate is provided. The substrate can include a bonding surface having a plurality of bonding regions. The skilled artisan will appreciate in view of the disclosure herein that, at this stage, the plurality of bonding regions may not be physically separated. In block two 704, at least one bumper is provided on the bonding surface. In some embodiments, the at least one bumper extends above the bonding surfaces of the substate by a bumper height. In some embodiments, the at least one bumper separates the bonding regions of the bonding surface. In block three 706, the bonding surface is prepared for hybrid bonding, as described herein. It will be understood that at least planarization of the preparation can be conducted prior to providing the at least one bumper, and any activation and/or termination can be performed before or after providing the at least one bumper. Thus block 706 can be performed before, after or split between both before and after, block 704. In some embodiments, only die bonding surfaces are activated and/or terminated, and the substrate bonding surface need not be. In block four 708, a plurality of dies is directly bonded on the bonding surfaces, without an intervening adhesive. In some embodiments, the bumpers may be formed on the activated surface. For example, the bumper may be coated by physical vapor deposition (PVD) methods, for example by evaporating the bumper material through a mask on the surface of the substrate.

The method 700 will be understood to depict a simplified method of forming some embodiments of a bonded structure, e.g., 300, 400, 500, 600. The remaining figures depict various, more detailed methods of forming various types of bonded structures. For example, in each of the methods disclosed below, each die pocket 814, 914, 1114, 1214, 1314, 1414, 1514 is depicted as being configured to accommodate only one die widthwise. However, the skilled artisan will appreciate that, in variants of the illustrated processes, any die pocket can, instead, be configured to accommodate a plurality of laterally adjacent dies, as shown, e.g., in FIGS. 5A-5D.

FIGS. 8A-8K depict one method of forming a first type of bonded structure (e.g., singulated bonded structure 805 of FIG. 8K). The bonded structure 800 formed by the method depicted in FIGS. 8A-8K is one nonlimiting example of a bonded structure that comprises at least one bumper 810 that comprises a common material with an upper surface of the substrate 804 and is monolithic with the upper surface of the substrate 804.

FIG. 8A depicts a substrate 804. The substrate 804 has a planar smooth or substantially planar smooth substrate surface 807 largely defined by insulating materials suitable for direct bonding. At least partially embedded within the substrate 804 and exposed at the surface are a plurality (e.g., tens, hundreds, thousands, or more) of conductive features 809. The plurality of conductive features 809 are smooth or substantially smooth, with a surface coplanar or substantially coplanar with the substrate surface 807. As explained herein (and shown at least in FIG. 8H), the conductive features 809 are configured to be bonded (e.g., directly bonded, without the use of an intervening adhesive) to a die (e.g., die 806 of FIG. 8H), but will be subject to etching at a later stage, such that the degree to which the conductive features 809 are coplanar with, slightly recessed relative to, or slightly protruding relative to the surrounding dielectric surfaces is not important at this stage.

The substrate 804 can be, e.g., a carrier, an interposer, a wafer, a reconstituted wafer, a singulated element, or an integrated device die. In some embodiments, the substrate 804 can comprise a semiconductor bulk material 804a, e.g., silicon, gallium-nitride, etc., and a bonding layer 804b that includes both insulating material, such as silicon oxide, silicon nitride, silicon oxynitride, silicon carbide, silicon carbonitride, silicon oxycarbide, etc., and the conductive features 809. The bonding layer 804b can represent upper layer(s) of a back-end-of-line (BEOL) structure over active devices of an integrated circuit. The conductive features 809 can comprise a metal, e.g., copper, copper alloy, gold, gold alloy, silver, silver alloy, nickel, nickel alloy, palladium, palladium alloy, or combinations thereof etc.

FIG. 8B depicts the substrate 804 of FIG. 8A with a mask 811 selectively formed onto the substrate surface 807. The mask 811 can comprise an organic or inorganic layer (e.g., a photoresist) that is deposited (e.g., spin-coated) onto the substrate surface 807. In some embodiments, the mask 811 is deposited onto the substrate surface 807 and patterned (e.g., by selective exposure, development and dissolution) such that the mask 811 exposes desired bonding regions, including a plurality of the conductive features 809.

FIG. 8C depicts the substrate 804 of FIG. 8B selectively recessed (e.g., etched). The exposed substrate surface is selectively recessed (e.g., etched) to form die pockets 814. The substrate 804 can be etched by, e.g., RIE or wet etch methods. An etch technique can be selective to the insulating material of the bonding layer 804b, such that the conductive features 809 are shown protruding above the recessed surface of the die pockets 814.

FIG. 8D depicts the subject of FIG. 8C after the mask 811 is removed. In some embodiments, the resist 811 can be stripped, and the substrate 804 can be cleaned. The substrate 804 has a plurality of die pockets 814. The die pockets 814 have a recessed surface that has a depth below the substrate surface 807 of a bumper height 812. In some embodiments, as shown, the plurality of conductive features 809 protrude above the recessed surface of the die pocket 814. The non-recessed portions of the substrate 804 (e.g., the portions that were previously covered by the mask 811), which separate neighboring die pockets 814, can serve as bumpers 810. The bumpers 810 are configured to confine dies 806 (see FIG. 8G) to their intended die pocket 814, thereby reducing the incidence of a misaligned die interfering with the placement or function of a neighboring die. In some embodiments, the bumper height 812 is large enough to restrict translation and/or rotation of dies (e.g., dies 806 in FIG. 8G) that are placed in the die pocket 814. In some embodiments, the bumper height 812 is smaller than the thickness of die 806 (see FIG. 8G, which shows a die 806 having a die thickness 817). In the illustrated embodiment, the degree of recessing is less than a thickness of the conductive features 809. In some embodiments, the bumper height (e.g., bumper height 812) can be about 20 nm, 25 nm, 50 nm, 75 nm, 100 nm, 200 nm, 300 nm, 400 nm, 500 nm, 600 nm, 700 nm, 750 nm, 800 nm, 900 nm, 1 micron, 2 microns, 3 microns, 4 microns, 5 microns, 10 microns, or 15 microns, or any range between any of the foregoing heights.

FIG. 8E depicts an enlarged view of a die pocket 814. The die pocket 814 is recessed (e.g., etched) into the substrate 804, and particularly into the bonding layer 804b of the substrate 804. The die pocket 814 comprises a recessed surface, which extends below the original substrate surface 807 by a bumper height 812. The non-recessed surfaces of the substrate 804 adjacent to, and at least in part defining, the die pocket 814 serve as bumpers 810. The die pockets 814 further define and separate bonding regions 803 from one another, configured to be bonded to a die (e.g., the die 806 in FIG. 8G). The die pocket 814 has a pocket width 813. The pocket width 813 is larger than the width of any die configured to be placed within the die pocket 814. The conductive features 809 are also exposed within the die pocket 814, and they are shown protruding above the recessed surface of the die pocket 814.

FIG. 8F depicts a microelectronic structure 802, in which the conductive features 809 are recessed (e.g., selectively etched) to below a resulting substrate bonding surface 815 of the die pockets 814, which is typical of hybrid bonding as explained herein. FIG. 8F exaggerates the extent to which the conductive features 809 are recessed below the bonding surface 815. As depicted in FIG. 8F, the die pockets 814 are separated from neighboring die pockets 814 by the bumpers 810, which extend above the bonding surface 815 by a bumper height 812. The substrate bonding surface 815 has an appropriate planarity for direct bonding, as it was formed by relatively slight and uniform etching from the planarized surface of surface 807 of FIG. 8A, and the substrate bonding surface 815 can be activated and/or terminated at this stage for direct bonding, as described herein. Alternatively, only the bonding surfaces of the dies 806 to be bonded (see FIG. 8G) may be activated and/or terminated for direct bonding.

FIG. 8G depicts a plurality of dies 806 above the microelectronic structure 802 of FIG. 8F. The microelectronic structure 802 comprises a substrate 804 with a substrate surface 807. Recessed into the substrate 804 are die pockets 814, which comprise a bonding surface 815 below the substrate surface 807 by a bumper height 812. Die pockets 814 have a pocket width 813, which is the width between the bumpers 810. Embedded in the substrate 804 within the die pockets 814 are a plurality of conductive features 809.

Each die 806 can be an integrated circuit or other semiconductor device, such as solid state memory, or individual active or passive devices as described above. Each die 806 comprises a die substrate 816 with die conductive features 818 embedded therein. Each die has a die width 820 and a die thickness 817. The die thickness 817 is typically greater than 10 μm or even greater than 100 μm when they are ready for direct bonding. In other embodiments, the dies can be much thicker, such as the thickness of a wafer from which they were formed (e.g., 750 μm), and thinning can be conducted after bonding the dies 806 to the substrate 804 if desired.

The die substrate 816 can comprise a similar or different material from the bonding layer 804b of the substrate 804 of the microelectronic structure 802. The die conductive features 818 can comprise a similar or different material from the conductive features 809 of the microelectronic structure 802. The die width 820 can be less than the pocket width 813 in order to fit within the die pocket 814. And as described above, in some embodiments, the die thickness 817 can be greater than the bumper height 812. The microelectronic structure 802 is configured to be hybrid bonded to the dies 806. Accordingly, the dies 806 can have planarized surfaces suitable for direct bonding, and the die conductive features 818 may be recessed relative to the dielectric surface of the die substrate 816 in which they are embedded. As noted above, either or both of the substrate bonding surface 815 and/or the die bonding surface regions (not separately labeled) may additionally be activated and/or terminated for direct bonding.

FIG. 8H depicts a bonded structure 800, wherein the dies 806 depicted in FIG. 8G are hybrid bonded to the microelectronic structure 802 depicted in FIG. 8G. The die conductive features 818 are configured to be directly bonded to the conductive features 809 of the microelectronic structure 802 without any intervening adhesive, and insulating surfaces of the die substrates 816 that surround or embed the die conductive features 818 are configured to be directly bonded to the substrate 804 of the microelectronic structure 802 without any intervening adhesive. Each die 806 is narrow enough to fit within its die pocket 814. In other words, the pocket width 813 (see FIG. 8G) is greater than the die width 820 (see FIG. 8G).

FIG. 8H is similar to FIG. 3B. In some embodiments, the pocket width (e.g., 813) can exceed the die width (e.g., 820) by about or at least 0.5 microns, 1 micron, 2 microns, 3 microns, 4 microns, 5 microns, 6 microns, 7 microns, 8 microns, 9 microns, 10 microns, or by any range between any of the foregoing dimensions.

Referring still to FIG. 8H, it will also be appreciated that, although each die pocket 814 (shown in FIG. 8G) is only configured to constrain a single die 806, a single die pocket 814 can be configured to constrain a plurality of dies (as shown, e.g., in FIG. 5B). After the bonding operation, the bonded structure 800 may be annealed at a higher temperature ranging between 50° C. to 400° C. in a suitable oven with a suitable ambient, to strengthen the bonding interface between the die 806 and the bonding layer 804b. For embodiments in which the conductive features (e.g., conductive features 809 of the microelectronic structure 802 and/or conductive features 818 of the dies 806) had been recessed relative to the adjacent dielectric surface before the bonding operation, an anneal can additionally electrically connect the conductive features 818 of the die 806 and the conductive features 809 of the microelectronic structure 802. The annealing times for the bonded structure 800 may range between 3 minutes to more than 4 hours. The temperature of the annealing oven may be ramped up at a rate between 2° C./minute to 50° C./minute to the highest annealing temperature. Also, the temperature of the annealing oven may be ramped down in a similar controlled manner. The annealing ambient may comprise a vacuum, an inert ambient, a reducing ambient, an oxidizing ambient, and/or an ambient comprising products of a plasma. The products of the plasma may, for example, comprise excited species of hydrogen, nitrogen, helium, argon or silane. In some embodiments, the annealing protocols may comprise annealing the bonded structure 800 at multiple temperatures. For example, the annealing protocol may comprise annealing the bonded structure stepwise at 80° C. for 30 minutes followed by 150° C. for 30 minutes and 250° C. for 30 minutes or longer. Similarly, in some embodiments the bonded structure 800 may be cooled from the highest annealing temperature in a controlled stepwise down ramp.

FIG. 8I depicts the bonded structure 800 of FIG. 8H after being coated in a protective layer 830 and singulated into singulated bonded structures 805. The singulated bonded structure 805 may serve as individual packages or may be further processed to form individual packages. The protective layer 830 is disposed on top of the bonded structure 800 of FIG. 8H. The protective layer 830 can inhibit or prevent singulation debris from contaminating the bonded structure 800. The protective layer 830 can comprise an organic or inorganic layer (e.g., a photoresist) that is deposited (e.g., spin-coated) onto the bonded structure 800 of FIG. 8H. Additional details of examples of the protective layer may be found throughout U.S. Pat. No. 10,714,449, the entire contents of which are incorporated by reference herein in their entirety and for all purposes.

The bonded structure 800 can be singulated using any suitable method, such as saw singulation, laser singulation, etc. Before the bonded structure 800 is singulated, in some embodiments, the bonded structure 800 can be temporarily disposed onto a temporary carrier 840. In some embodiments, the temporary carrier 840 is a dicing tape or film, which can be held at a perimeter by a film frame. In other embodiments, the temporary carrier 840 can comprise a glass or silicon substrate. After the substrate 804 of the bonded structure 800 is disposed onto the temporary carrier 840, the bonded structure 800 can be singulated. In some embodiments, singulation can be achieved by sawing, RIE, or lasering grid lines to separate the singulated bonded structures 805 from one another, without cutting all the way through the temporary carrier 840. In some embodiments, after singulation, the singulated bonded structures 805 remain supported by the temporary carrier 840.

FIG. 8J shows the singulated bonded structures 805 of FIG. 8I after the protective layer 830 has been removed. The protective layer 830 can be removed from each singulated bonded structure 805 with a cleaning agent, for example with a suitable solvent, such as an alkaline solution, oxygen plasma ashing, or other suitable technique. After the protective layer 830 is removed, the singulated bonded structures 805 can be cleaned. The cleaning process may include rinsing the singulated bonded structures 805 with deionized water (DI) or other recommended cleaning agents and spin drying the bonded substrates 805 while they are still attached to the carrier 840. It will be appreciated that “bonded structure” can refer to a presingulated structure (e.g., FIG. 8H) and to a post-singulation structure (e.g., FIGS. 8I-8K).

FIG. 8K depicts a bonded structure, namely the singulated bonded structure 805, made by the method shown in FIGS. 8A-8K. This singulated bonded structure 805 comprises a die 806 directly bonded within a shallow die pocket 814 to a bonding surface 815 that extends below the substrate surface 807 by a bumper height 812. In some embodiments, the pocket width 813 is greater than the die width 820. In some embodiments, the die thickness 817 is greater than the bumper height 812. The die 806 is constrained by the bumpers 810, which can be continuous (see, e.g., FIGS. 3A, 3B, 4A, 4B, 5A-5D, and 6D) or discontinuous (see, e.g., FIGS. 6A-6C and FIGS. 6E-6H). In some embodiments (not shown), the pre-singulation bonded structure may be overmolded, and singulation though the mold leaves a package that includes mold encapsulating the die 806, die pocket 814 and tops of the bumper(s) 810, with bumper 810 and substrate 804 sidewalls that are flush with the mold sidewalls. In such an embodiment, the temporary protective layer 830 of FIG. 8I may be omitted. In other embodiments, the singulated bonded structure 805 of FIG. 8K can be subsequently packaged with other elements, such as further directly bonded elements on the backside of the die 806 and/or overmolding.

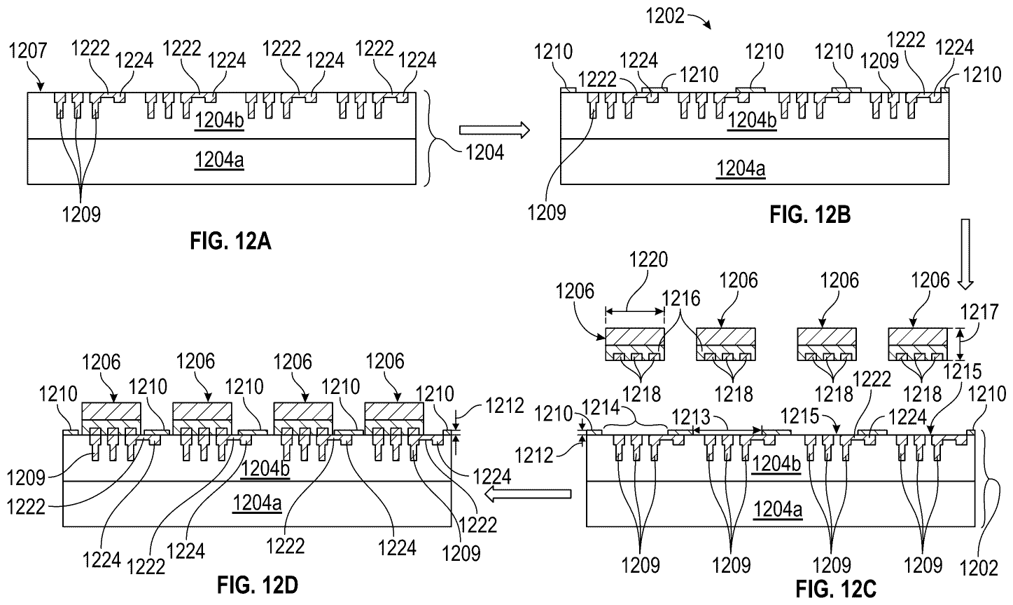

FIGS. 9A-9I depict one method of forming a second type of bonded structure (e.g., singulated bonded structure 905 of FIGS. 9H and 9I). The bonded structure 900 formed by the method depicted in FIGS. 9A-9I is one nonlimiting example of a bonded structure that comprises at least one bumper 910 that comprises a deposited material over the substrate 904. In the illustrated embodiment, the at least one bumper 910 comprises a conductive material.

FIG. 9A is analogous to FIG. 8A. FIG. 9A depicts a substrate 904. The substrate 904 has a planar smooth or substantially planar smooth substrate surface 907. largely defined by insulating materials suitable for direct bonding. At least partially embedded within the substrate 904 are a plurality (e.g., tens, hundreds, thousands, or more) of conductive features 909. The plurality of conductive features 909 are smooth or substantially smooth, with a surface substantially coplanar with the substrate surface 907. It will be understood in view of disclosure herein that the conductive features 909 can be slightly protruding or slightly recessed relative to the surrounding insulating materials of the substrate 904. As in the embodiment of FIG. 8A, the substrate can include a bulk semiconductor material 904a and a bonding layer 904b, which can be part of a BEOL or redistribution layer (RDL) structure. The substrate 904, substrate surface 907, and conductive features 909 depicted in FIG. 9A are similar to the substrate 804, substrate surface 807, and conductive features 809 depicted in FIG. 8A and described herein.

In addition to the features also depicted in FIG. 8A, FIG. 9A also depicts peripherally located traces 922 and conductive pads 924, which can serve as test or probe pads. In some embodiments, the conductive pads 924 can serve as probe pads at the stage of FIG. 9A to test the devices within the substrate 904 at the wafer level, in which case the conductive pads may include surface markings, scratches, and/or protrusions indicative of probe contact. The traces 922 and conductive pads 924 can be at least partially embedded within the substrate 904. The traces 922 and conductive pads 924 can comprise a conductive material, e.g., aluminum, copper, gold, silver, nickel, palladium, platinum, and alloys thereof, etc. The traces 922 and conductive pads 924 can be in electrical communication with one or more conductive features 909.

FIG. 9B depicts the structure of FIG. 9A with a mask 911 selectively formed and patterned on the substrate surface 907. In some embodiments, the mask 911 depicted in FIG. 9B is similar to the mask 811 described with respect to FIG. 8B, and can comprise a resist, such as photoresist. Whereas the mask 811 depicted in FIG. 8B is not deposited on top of a plurality of the conductive features 809, the mask 911 depicted in FIG. 9B can be patterned to remain over a plurality of the conductive features 909. In FIG. 9B, the mask 911 is patterned to expose the conductive pads 924 and may also expose portions of the traces 922 as shown. As is described below, whereas the die pocket 814 in FIGS. 8A-8K substantially corresponded to the portion of the substrate surface 807 that was not covered by the mask 811 in FIG. 8B, the die pocket 914 (FIG. 9D) in FIGS. 9A-9I substantially correspond to the portion of the substrate surface 907 that is covered by the mask 911 in FIG. 9B

FIG. 9C depicts the subject of FIG. 9B with conductive material 926 disposed on the mask 911 and exposed portions of the substrate 904. The conductive material 926 is electrically conductive and can comprise, e.g., aluminum, nickel, nickel alloys, copper, copper alloys, etc. The conductive material 926 can be disposed onto the substrate 904 and mask 911 by any suitable method, such as PVD—of which, examples include sputtering or evaporation. In other embodiments, the conductive material 926 can be selectively formed on the exposed conductive pads 924 and traces 922, such as by electroless plating or electroplating. The conductive material 926 of FIG. 9C is disposed at least partially on traces 922 and conductive pads 924. In this way, the conductive material 926 is in electrical communication with conductive pads 924, which in turn is in electrical communication with traces 922, which in turn is in electrical communication with at least one conductive feature 909. The thickness of the conductive material 926 can define a bumper height 912 (shown in FIG. 9D).

FIG. 9D depicts a microelectronic structure 902 that is configured to be hybrid bonded without an intervening adhesive to dies, e.g., dies 906 (shown in FIG. 9E). To get from the structure depicted in FIG. 9C to the structure depicted in FIG. 9D, the mask 911 and the conductive material 926 disposed over the resist 911 are removed. The mask 911 can be stripped, removing any overlying conductive material 926 by lift-off patterning, and the substrate 904 can be cleaned. If not already activated at the stage of FIG. 9A, the exposed substrate surface 907 can be activated and prepared for hybrid bonding at the stage of FIG. 9D, as disclosed herein. At least a portion of the exposed substrate surface 907 that is activated and prepared for bonding is the bonding surface 915.

The microelectronic structure 902 comprises a substrate 904 with conductive elements (e.g., conductive features 909, traces 922, and conductive pads 924) at least partially embedded therein. The substrate 904 comprises a substrate surface 907. A portion of the substrate surface 907 is exposed (i.e., not covered by conductive material 926), and at least a portion of the exposed substrate surface 907 comprises a bonding surface 915. Another portion of the substrate surface 907 has conductive material 926 disposed thereover. The conductive material 926 serves as a bumper 910. The bumpers 910 extend above the bonding surface 915 by a bumper height 912, which can be analogous to the bumper height 812 of, e.g., FIG. 8D.

The microelectronic structure 902 of FIG. 9D further comprises die pockets 914 bordered by the bumpers 910. Like the die pockets 814 of, e.g., FIG. 8G, the die pockets 914 of FIG. 9D have a bonding surface 915 configured to be bonded to dies (e.g., dies 906, shown in FIG. 9E). The die pockets 914 are separated from neighboring die pockets 914 by at least one bumper 910, with the at least one bumper 910 extending above the bonding surface 915 by a bumper height 912. Also, the pocket width 913 is greater than the die width 920 (shown in FIG. 9E).

FIG. 9E depicts a bonded structure 900, in which a plurality of dies 906 are bonded to the microelectronic structure 902 depicted in FIG. 9D. The dies 906 can be hybrid bonded to the microelectronic structure 902, without an intervening adhesive, such as by directly bonding insulating materials of the dies 906 to insulating materials of the die pockets 914 of the substrate 904 at room temperature, followed by annealing to join conductors 909, 918. The dies 906 are disposed into die pockets 914 depicted in FIG. 9D. The dies 906 and their configuration within a die pocket 914 is similar to those of FIGS. 8G-8H: each die 906 comprises a die substrate 916 and die conductive features 918; the die conductive features 918 are configured to be aligned with and directly bonded to the conductive features 909 of the microelectronic structure 902 without any intervening adhesive, and insulating materials of the die substrates 916 are configured to be directly bonded to the insulating materials of the substrate 904 of the microelectronic structure 902 without an intervening adhesive. In some embodiments (e.g., those depicted in FIGS. 9E-9I), there is a gap between each bumper 910 and adjacent dies 906. The gap may be coated with an underfill layer 928 (shown in FIG. 9I). In some embodiments (not shown), there is no such gap between a bumper and adjacent dies. An additional feature of bonded structure 900 is that each die 906 can be in electrical communication with at least one bumper 910 by way of the electrical path established between the die conductive features 918, conductive features 909 of the microelectronic structure 902, traces 922, conductive pads 924, and bumper 910, which comprises conductive material 926.

In some embodiments, the completed circuits for the bonded structure 900 can be tested at this stage, prior to singulation, by way of the bumpers 910, which can serve as probe pads, to determine known good die pairs while still at the wafer level.

FIG. 9F is analogous to FIG. 8I: FIG. 9F depicts the bonded structure 900 of FIG. 9E after being coated in a protective layer 930 and singulated into singulated bonded structures 905. It will be understood that before the bonded structure 900 is singulated, in some embodiments, the bonded structure 900 can be temporarily disposed onto a temporary carrier 940. The temporary carrier 940 depicted in FIG. 9F can be analogous to the temporary carrier 840 depicted in FIGS. 8I-8J and described herein. In the illustrated embodiment, the singulation (e.g., saw cut) leaves at least some of the bumpers 910 intact and available for either probing or permanent circuit connection; in other embodiments, the singulation can obliterate some or all of the bumpers and underlying conductive pads.

FIG. 9G is analogous to FIG. 8J: FIG. 9G depicts the subject of FIG. 9F, but after the protective layer 930 has been removed and the remaining dies 906 and microelectronic structures 902 have been cleaned. The singulated bonded structures 905 each comprise at least one die 906 and at least one electrically conductive bumper 910, wherein the at least one die 906 is in electrical communication with the at least one bumper 910.

FIG. 9H depicts the singulated bonded structure 905 made by the method shown in FIGS. 9A-9G after removal from the dicing tape or temporary carrier. This bonded structure 905 comprises a die 906 directly bonded within a shallow die pocket 914 of the microelectronic structure 902. The die 906 is bonded to a bonding surface 915 of the die pocket 914. Adjacent to the die pocket 914 is a bumper 910 that extends above the bonding surface 915 by a bumper height 912. The bumper 910 is in electrical communication with the die 906, by way of the conductive pad 924, trace 922, conductive features 909 of the microelectronic structure 902, and die conductive features 918. Two dimensions of die 806 include die thickness 917, which is greater than the bumper height 912, and the die width 920, which is less than the pocket width 913.

FIG. 9I depicts the singulated bonded structure 905 of FIG. 9H but shows use of an underfill 928 to seal any gap between the die 906 and the bumper 910.

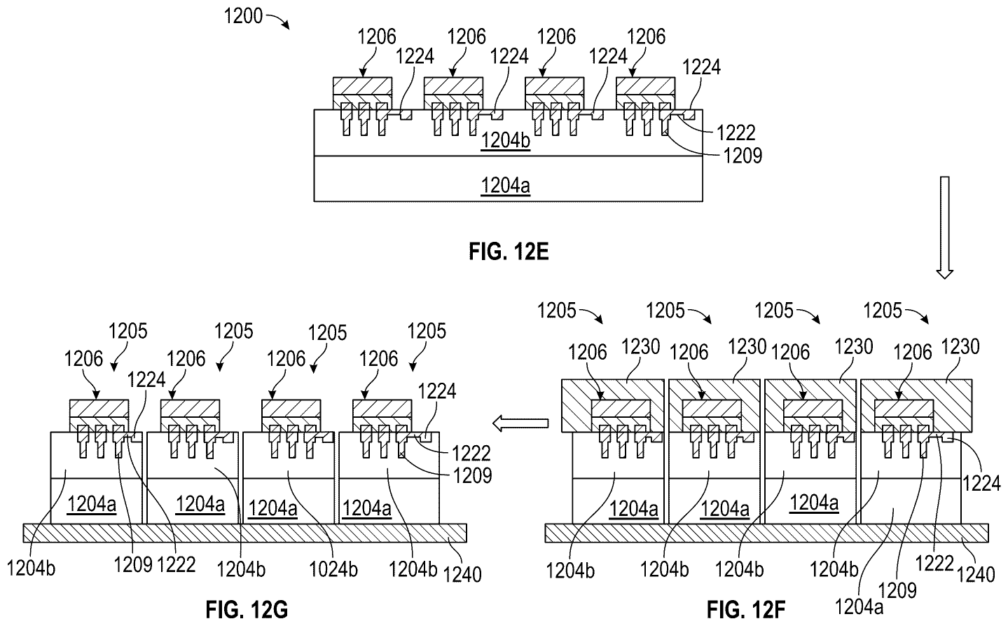

FIGS. 10A-10C depict various configurations wherein the bonded structure 905 of FIG. 9H can be electrically connected to a commonly packaged external circuit (CPEC) 1050, and the bumper 910 can serve as an active input/output pad rather than (or in addition to) a probe pad. FIG. 10A depicts a carrier 1060, such as a printed circuit board (PCB) or other packaging substrate, on which both bonded structure 905 and CPEC 1050 are disposed. The electrically conductive bumper 910 of the bonded structure 905 is electrically connected to CPEC 1050 with an electrical connector 1070. The electrical connector 1070 can comprise a wire bond, and the CPEC 1050 is represented by a simple bond pad of the carrier 1060, which can connect to circuits within the carrier 1060 or connected through the carrier 1060 to other commonly packaged microelectronic elements. FIG. 10B is similar to FIG. 10A, except that the CPEC 1050 of FIG. 10B is a commonly packaged die, and the other die is disposed on the carrier 1060 with bond pad 1080. Like FIG. 10B, FIG. 10C depicts the electrically conductive bumper 910 being electrically connected (by way of the electrical connector 1070) to the CPEC 1050 by way of a bond pad 1080. In FIG. 10C, the CPEC 1050 is also another die with a bonding pad 1080 connected to the electrically conductive bumper 910 by way of the electrical connector 1070. In FIG. 10C, however, the CPEC 1050 is bonded to the die 906 of bonded structure 905.

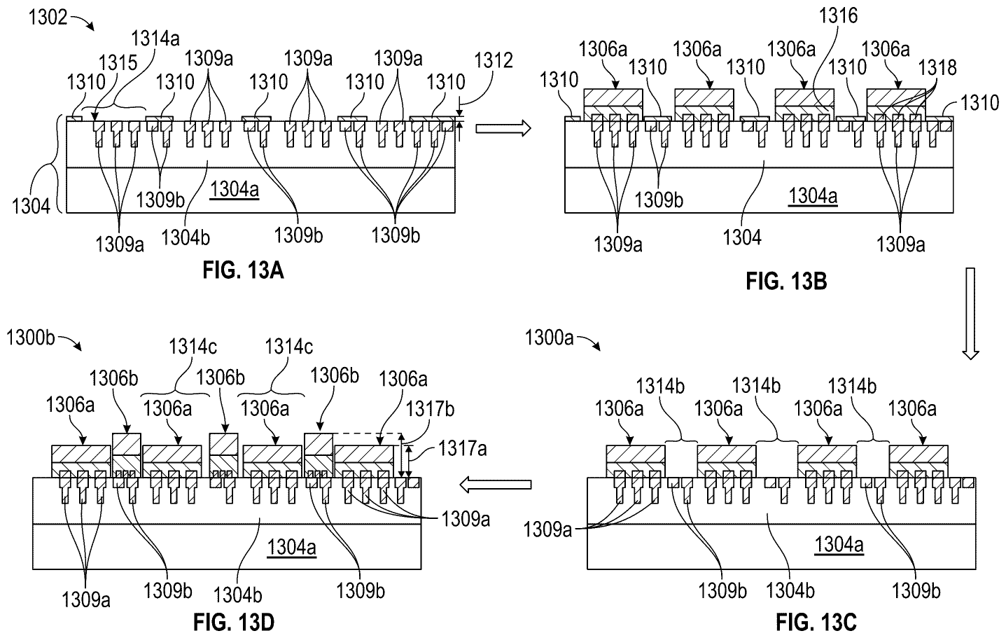

FIGS. 11A-11H depict one method of forming a third type of bonded structure (e.g., bonded structures 1100 of FIG. 11E or 1105 of FIG. 11H). The bonded structure 1100 or 1105 formed by the method depicted in FIGS. 11A-11H is one nonlimiting example of a bonded structure that comprises at least one bumper 1110 that is disposed on the substrate 1104, wherein the at least one bumper 1110 can be a feature of the final bonded structure 1100 (shown in FIG. 11H).

FIG. 11A is the same as FIG. 8A, but with reference numerals incremented to reflect the figure number. FIG. 11A depicts a substrate 1104, comprising a bulk semiconductor 1104a and a bonding layer 1104b, with a planar smooth or substantially planar smooth substrate surface 1107. At least partially embedded within the substrate 1104 are a plurality (e.g., tens, hundreds, thousands or more) of conductive features 1109. The plurality of conductive features 1109 are smooth or substantially smooth, with a surface coplanar or substantially coplanar with the substrate surface 1107, and may be slightly recessed or protruded with respect to the surrounding dielectric material. As explained herein (and shown at least in FIG. 11E), the dielectric material of the bonding layer 104b is suitable for direct bonding, and the conductive features 1109 are configured to be bonded (e.g., directly bonded, without the use of an intervening adhesive) to a die (e.g., the die 1106 of FIG. 11E).

FIG. 11B depicts a plurality of bumpers 1110 disposed onto the substrate surface 1107 of the substrate 1104. The bumpers 1110 can comprise dielectric material (e.g., silicon oxide, silicon nitride, silicon carbide, or another dielectric such as organic dielectrics) or non-dielectric material (e.g., metals or semiconductors). In some embodiments, bumpers 1110 can be electroplated, e.g., after a mask is patterned over the substrate 1104 in an intermediate step. In some embodiments, the bumpers 1110 can be deposited, such as by sputtering or chemical vapor deposition, and subsequently patterned. In some embodiments, the bumpers 1110 can be patterned in the deposition process, such as by screen printing, deposition through a shadow mask, or deposited by a nozzle, e.g., 3-D printed, onto the substrate 1104. The bumpers 1110 extend above the substrate surface 1107 by a bumper height 1112 (shown in FIG. 11C).

FIG. 11C looks like FIG. 11B, but in FIG. 11C, portions of the substrate surface 1107 have been activated and prepared for hybrid bonding, as disclosed herein. Such activation can include rinsing the activated surface with an alkaline solution, or exposing the surface to a plasma. At least a portion of the substrate surface 1107 that is activated and prepared for bonding is the bonding surface 1115.

FIG. 11C depicts a microelectronic structure 1102 that is configured to be hybrid bonded without an intervening adhesive to dies, e.g., dies 1106 (shown in FIG. 11D). The microelectronic structure 1102 comprises a plurality of die pockets 1114 or bonding regions, configured to have dies (e.g., dies 1106, shown in FIG. 11D) disposed therewithin. Each die pocket 1114 has a pocket width 1113 between bumpers 1110. The bumpers 1110 extend above the bonding surface 1115 by a bumper height 1112. The pocket width 1113 is greater than the die width 1120 (shown in FIG. 11D), allowing die 1106 (shown in FIG. 11D) to fit within the die pocket 1114.

FIG. 11D is analogous to FIG. 8G. Numerals in this paragraph refer to FIG. 11D, not FIG. 8G. Both figures depict a plurality of dies 1106 above the microelectronic structure 1102, prepared to be hybrid bonded thereto, without an intervening adhesive. In both figures, each die 1106 is prepared to be bonded to a bonding surface 1115, and in both figures, each die pocket 1114, having a pocket width 1113, is separated from neighboring die pockets 1114 by at least one bumper 1110, which extend above the bonding surface 1115 by a bumper height 1112. In both figures, each die 1106 comprises a die substrate 1116 with die conductive features 1118 embedded therein. Each die has a die width 1120 and a die thickness 1117.

One difference between FIG. 11D and FIG. 8G is that, in FIG. 8G, the bumpers 810 are monolithic with the substrate 804, and particularly with the bonding layer 804b of the substrate 804, and were formed by etching the substrate surface 807; while in FIG. 11D, the bumpers 1110 are disposed onto the substrate 1104 and can thus be a different material from the bonding layer 1104b. Disposing bumpers 1110 onto the substrate 1104, as depicted in FIGS. 11D-11E, can offer flexibility with material choice. A wide variety of materials can be suitable for the bumpers 1110, so one can tailor materials for a bumper 1110 based on preference (e.g., cost, availability, strength, low thermal expansion coefficient). Disposing the bumpers 1110 onto the substrate 1104, as depicted in FIGS. 11D-11E, can also conserve material (and possibly cost) by not needing to remove material from the substrate 1104, e.g., by etching, and minimize risk of disturbing the planarity of the substrate surface 1107 that was provided to be suitable for direct bonding.

FIG. 11D provides a nonlimiting example. It will be appreciated that, while FIG. 11D depicts two bumpers 1110 between each pair of neighboring die pockets 1114, there could instead be one, three, or more. It will also be appreciated that, while FIG. 11D depicts exactly one die 1106 above each die pocket 1114, each die pocket 1114 can be configured to contain one or a plurality (two, three, ten, or more) of dies 1106 (as shown, e.g., in FIGS. 5A-5B). Suitable variations in bumper patterning and distribution can be as described with respect to FIGS. 6A-6H.

FIG. 11E is analogous to FIG. 8H. FIG. 11E depicts a presingulated bonded structure 1100, in which the dies 1106 depicted in FIG. 11D are disposed onto the microelectronic structure 1102 depicted in FIG. 11D, e.g., by hybrid bonding as described herein. As depicted in FIG. 11E, die conductive features 1118 are configured to be directly bonded to the conductive features 1109 of the microelectronic structure 1102 without any intervening adhesive, and die substrates 1116 are configured to be directly bonded to the substrate 1104 of the microelectronic structure 1102 without any intervening adhesive. Each die 1106 is narrow enough to fit within the corresponding die pocket 1114, e.g., the pocket width 1113 (see FIG. 11D) is greater than the die width 1120 (see FIG. 11D).

FIG. 11E is similar to FIG. 4B. It will be appreciated that the die pocket 1114 is sufficiently wider than the die 1106 bonded therein that, in the majority of cases, even if the die 1106 is misaligned (e.g., see misaligned die 308 of FIG. 3B), the die 1106 will still be constrained within the die pocket 1114. This extra width between the die width 1120 and pocket width 1113 reduces the likelihood that a misaligned die will interfere with the placement or function of dies in neighboring die pockets. The pocket width (e.g., 1113) can exceed the die width (e.g., 1120) by about or at least 0.5 microns, 1 micron, 2 microns, 3 microns, 4 microns, 5 microns, 6 microns, 7 microns, 8 microns, 9 microns, 10 microns, or any range therebetween. It will be appreciated that, if a die 1106 is misaligned, the die conductive features 1118 may not align with the conductive features 1109 of the microelectronic structure 1102, and the die substrate 1116 may not align with the substrate 1104 of the microelectronic structure 1102. In such an event, the misaligned die still effectively bonds to the bonding surface 1115 of the die pocket 1114, but may not be electronically effective, since the connections between conductive features 1109, 1118 may be misaligned. On the other hand, if die slippage is severe enough that the die 1106 does not fit within the die pocket 1114, it may not directly bond to the substrate 1104 and thus may be removed to avoid interfering with neighboring dies 1106 and possibly replaced with a second die 1106. The bonded structure 1100 maybe annealed at a higher temperature or temperatures prior to subsequent processes, as described herein.

FIG. 11F is analogous to FIG. 8I: FIG. 11F depicts the bonded structure 1100 of FIG. 11E after being coated in a protective layer 1130 and singulated into singulated bonded structures 1105. It will be understood that before the bonded structure 1100 is singulated, in some embodiments, the bonded structure 1100 can be temporarily disposed onto a temporary carrier 1140. The temporary carrier 1140 depicted in FIG. 11F can be analogous to the temporary carrier 840 depicted in FIGS. 8I-8J and described herein. In the illustrated embodiment, the singulation (e.g., saw cut) leaves at least some of the bumpers 1110 intact; in other embodiments, the singulation can obliterate some or all of the bumpers and underlying conductive pads.

FIG. 11G is analogous to FIG. 8J. FIG. 11G depicts the subject of FIG. 11F, but after the protective layer 1130 has been removed and the remaining dies 1106 and microelectronic structures 1102 have been cleaned. The singulated bonded structures 1105 comprise at least one die 1106 and at least one bumper 1110.

FIG. 11H depicts the bonded structure 1105 made by the method shown in FIGS. 11A-11G. This bonded structure 1105 comprises a die 1106 directly bonded within a shallow die pocket 1114 of microelectronic structure 1102. Die 1106 is bonded to a bonding surface 1115 of the die pocket 1114. Adjacent to the die pocket 1114 is a bumper 1110 that extends above the bonding surface 1115 by a bumper height 1112. Two dimensions of die 1106 include die thickness 1117, which is greater than bumper height 1112, and die width 1120, which is less than pocket width 1113 (as shown in FIG. 11D).

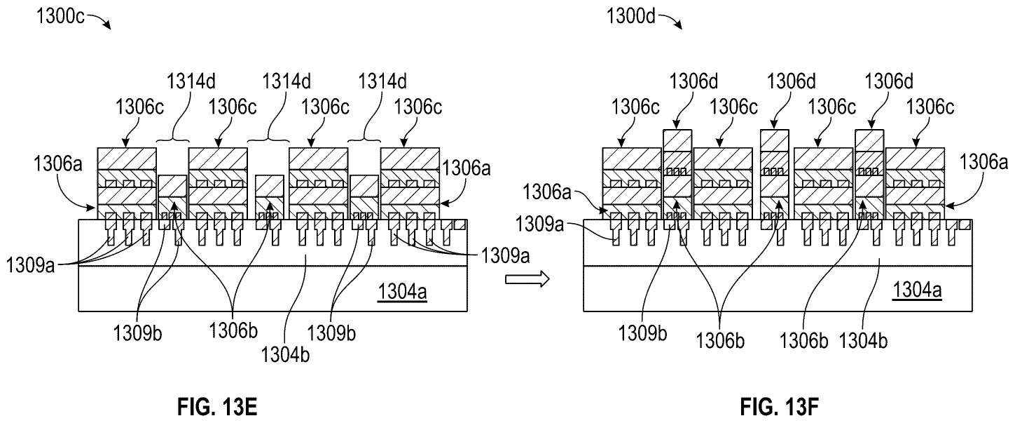

FIGS. 12A-12G depict one method of forming a fourth type of bonded structure (e.g., bonded structure 1200 of FIG. 12E, or the bonded structure 1205 of FIG. 12G). The bonded structure 1200 formed by the method depicted in FIGS. 12A-12G is one nonlimiting example of a bonded structure that utilizes temporary bumpers 1210 to constrain the placement of dies 1206 but that are not features of the final bonded structure 1205 (shown in FIG. 12G).

FIG. 12A is similar to FIG. 9A, with a plurality of conductive features 1209, peripheral traces 1222, and peripheral conductive pads 1224 at least partially embedded within a substrate 1204, which can include a bulk semiconductor 1204a and a bonding layer 1204b. The substrate surface 1207 can be planar smooth or substantially planar smooth. The conductive features 1209, traces 1222, and conductive pads 1224 can be planar smooth or substantially planar smooth, with surfaces coplanar or substantially coplanar with the substrate surface 1207. Unsingulated devices within the substrate 1204 can be probed at this point, in which case the pads 1224 can have indicia (such as scratches, protrusions) of having been probed.

FIG. 12B depicts a microelectronic structure 1202, in which the bumpers 1210 are disposed in a pattern onto the substrate surface 1207. The bumpers 1210 can be similar in function and dimension to bumpers used in other types of bonded structures (e.g., 810, 910, and 1110), but the bumpers 1210 differ from the others in that the bumpers 1210 are temporary, e.g., configured to be absent from the final bonded structure 1205 (shown in FIG. 12G). Many materials can be suitable for the temporary bumpers 1210. One such suitable material can comprise resist (e.g., photoresist), as described above with respect to the mask 811 (in, e.g., FIG. 8B) and the mask 911 (in, e.g., FIG. 9B). In some embodiments, as depicted in FIG. 12B, the temporary bumpers 1210 are disposed over at least a portion of the conductive pads 1224 and/or a portion of the traces 1222.

FIG. 12C is analogous to FIG. 8G, with dies 1206 depicted above the microelectronic structure 1202. The dies 1206 comprise die conductive features 1218, which can be at least partially embedded in the die substrate 1216, particularly in a bonding layer of the die substrate 1216, which can be one or more BEOL layer(s). The dies 1206 can each have a die width 1220 and a die thickness 1217. The microelectronic structure 1202 comprises the substrate 1204, at least partially embedded in which are the conductive features 1209, traces 1222, and conductive pads 1224. Disposed onto the substate 1204 are the temporary bumpers 1210, which extend above the bonding surface 1215 by a bumper height 1212, and which at least partially define a die pocket 1214.

FIG. 12D is analogous to FIG. 8H. FIG. 12D depicts the dies 1206 as being disposed onto the microelectronic structure 1202 of FIG. 12C. As depicted in FIG. 12D, the die conductive features 1218 are configured to be directly bonded to the conductive features 1209 of the microelectronic structure 1202 without any intervening adhesive, and the die substrates 1216, and particularly a bonding layer of the die substrates 1216, are configured to be directly bonded to the substrate 1204 of the microelectronic structure 1202 without any intervening adhesive. Each die 1206 is narrow enough to fit within the corresponding die pocket 1214, e.g., the pocket width 1213 (see FIG. 12C) is greater than the die width 1220 (see FIG. 12C).

FIG. 12E depicts the pre-singulated bonded structure 1200 of FIG. 12D. but after the temporary bumpers 1210 are removed. FIG. 12E captures a characteristic of using temporary bumpers 1210, namely, that they can be removed after dies 1206 are disposed onto microelectronic structure 1202. If the temporary bumpers 1210 comprise resist (e.g., photoresist), there are many conventional techniques by which such temporary bumpers 1210 can be removed. With removal of the temporary bumpers 1210, the conductive pads 1224 can be exposed such that they are available for probing at this stage, post-bonding of the dies to form the bonded structure 1200, or at a later stage. In some embodiments, the presingulated bonded structure 1200 may be annealed at a temperature lower than 130° C. for less than 30 minutes, such as at lower than or equal to about 100° C. to strengthen the bond between the dies 1206 and the bonding layer 1204b before stripping the temporary bumpers 1210. For embodiments in which the conductive features (e.g., conductive features 1209 of the microelectronic structure 1202 and/or conductive features 1218 of the dies 1206) had been recessed relative to the adjacent dielectric surface before the bonding operation, after stripping the temporary bumpers 1210 and cleaning the bonded structure 1200, the bonded structure 1200 may be annealed at a higher temperature to join the conductive features 1218 of the dies 1206 and the conductive features 1209 at least partially embedded in the bonding layer 1204b.

FIG. 12F is analogous to FIG. 8I: FIG. 12F depicts the bonded structure 1200 of FIG. 12E after being coated in a protective layer 1230 and singulated into singulated bonded structures 1205. It will be understood that before the bonded structure 1200 is singulated, in some embodiments, the bonded structure 1200 can be temporarily disposed onto a temporary carrier 1240. The temporary carrier 1240 depicted in FIG. 12F can be analogous to the temporary carrier 840 depicted in FIGS. 8I-8J and described herein. In the illustrated embodiment, the singulation (e.g., saw cut) leaves at least some of the conductive pads 1224 intact and available for either probing or permanent circuit connection; in other embodiments, the singulation can obliterate some or all of the peripheral conductive pads.

FIG. 12G is analogous to FIG. 8J. FIG. 12G depicts the subject of FIG. 12F, but after the protective layer 1230 has been removed and the remaining dies 1206 and microelectronic structures 1202 have been cleaned. The singulated bonded structures 1205 comprise at least one die 1206. The singulated bonded structures 1205 comprise no bumper 1210, since the temporary bumpers 1210 were previously removed. At least a portion of the conductive pads 1224 and/or a portion of the traces 1222 (both conductive elements) of singulated bonded structures 1200 are exposed (e.g., not bonded to or otherwise covered by a die 1206). Since singulated bonded structures 1205 have such exposed conductive elements that are in electrical communication with the die 1206, one can electrically connect the die 1206 to an external circuit (e.g., a commonly packaged external circuit, e.g., 1050 in FIGS. 10A-10C) by connecting the external circuit to the exposed trace 1222 or exposed conductive pad 1224, either for probing the bonded structures 1205 at this stage or for functional input/output use in the final product.

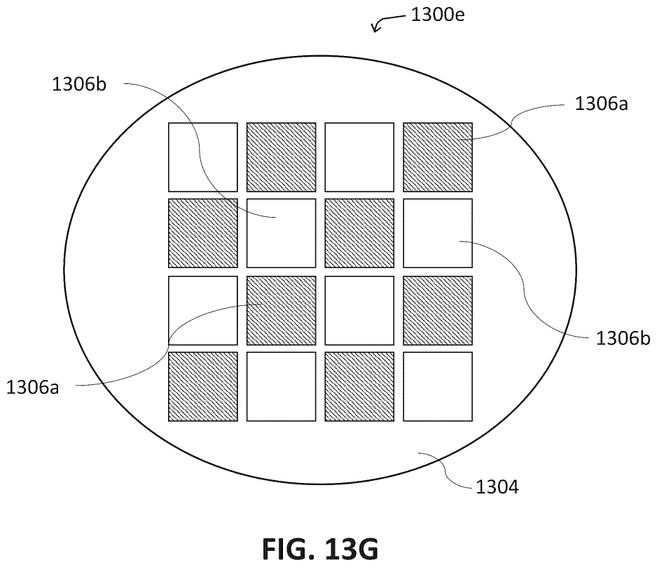

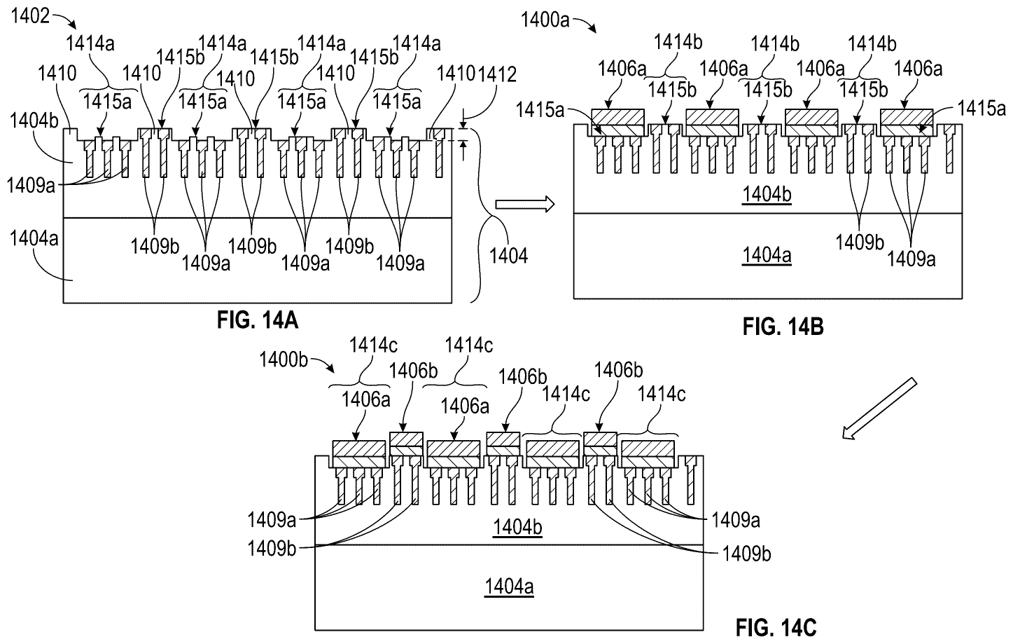

FIGS. 13A-13F depict one method of forming a fifth type of bonded structure (e.g., bonded structures 1300a, 1300b, 1300c, 1300d of FIGS. 13C-13F). The method depicted in FIGS. 13A-13F and described herein is another nonlimiting example of how temporary bumpers (e.g., 1210 shown in FIGS. 12B-12D) can be implemented. The bonded structure 1300d formed by the method depicted in FIG. 13F is one nonlimiting example of a bonded structure that utilizes temporary bumpers 1310 (FIG. 13B) to constrain the placement of a first plurality of dies 1306a onto a first plurality of conductive features 1309a, then utilizes the first plurality of dies 1306a to constrain the placement of a second plurality of dies 1306b onto a second plurality of conductive features 1309b, then utilizes the second plurality of dies 1306b to constrain the placement of a third plurality of dies 1306c on top of the first plurality of dies 1306a, then utilizes the third plurality of dies 1306c to constrain the placement of a fourth plurality of dies 1306d on top of the second plurality of dies 1306b.

It will be understood that before any dies (e.g., 1306a, 1306b, 1306c, 1306d) are disposed (e.g., direct bonded or hybrid bonded, without an intervening adhesive) onto another feature (e.g., to the substrate 1304 or another die 1306a, 1306b), one or both surfaces to be bonded can be planarized, activated, and/or terminated for direct bonding, as described herein.

FIG. 13A depicts a microelectronic structure 1302 comprising a substrate 1304, including a bulk semiconductor region 1304a and a bonding layer 1304b, and temporary bumpers 1310. FIG. 13A is similar to FIG. 12B except that two separate groups of conductive features 1309a, 1309b are included in the substrate 1304, only one group of which is covered by the temporary bumper 1310. The conductive features 1309a, 1309b can be similar to other conductive features described herein (e.g., 809 of FIG. 8A, 909 of FIG. 9A, 1109 of FIG. 11A, and 1209 of FIG. 12A). The temporary bumpers 1310 can be similar (e.g., in material, dimensions, and function) to the temporary bumpers 1210 of FIG. 12B. The gaps between neighboring bumpers 1310 form a first plurality of die pockets 1314a, configured to constrain the first plurality of dies 1306a.

The first plurality of conductive features 1309a are configured to be bonded to the first plurality of dies 1306a (shown in FIG. 13B). The second plurality of conductive features 1309b are depicted in FIG. 13A as being covered by temporary bumpers 1310. The second plurality of conductive features 1309b are configured to be bonded to the second plurality of dies 1306b (shown in FIG. 13D), after the first plurality of dies 1306a are bonded to the first plurality of conductive features 1309a (shown in FIG. 13B), and after the temporary bumpers 1310 are removed (shown in FIG. 13C).

FIG. 13B is similar to FIG. 12D, in that they both depict dies (dies 1206 in FIG. 12D, and the first plurality of dies 1306a in FIG. 13B) being disposed onto the microelectronic structure (1302 in FIG. 13A, 1202 in FIG. 12C), in similar ways.

FIG. 13C depicts an initial bonded structure 1300a, comprising a microelectronic structure 1302 on which a first plurality of dies 1306a have been disposed. FIG. 13C is similar to FIG. 12E, in that they both depict the removal of temporary bumpers (1310 of FIG. 13B, 1210 of FIG. 12D). After the bumpers 1310 are removed, the initial bonded structure 1300a can be cleaned. In FIG. 13C, the removal of the temporary bumpers 1310 exposes the second plurality of conductive features 1309b. In some embodiments, after bonding the first plurality of dies 1306a as depicted in FIG. 13B, the bonded structure may be annealed at a temperature lower than 130° C. or at a temperature lower than 90° C. for annealing times of less than 120 minutes to improve the bond strength or energy between the dies 1306a and the host substrate 1304 prior to stripping of the temporary bumpers 1310.

The gaps between neighboring dies of the first plurality of dies 1306a form a second plurality of die pockets 1314b, configured to constrain the second plurality of dies 1306b. Effectively, the first plurality of dies 1306a serve as bumpers that reduce the likelihood that a misplaced die from among the second plurality of dies 1306b will interfere with the placement of any neighboring dies.

FIG. 13D depicts a bonded structure 1300b, comprising a microelectronic structure 1302 on which the first and second plurality of dies 1306a, 1306b have been disposed. The second plurality of dies 1306b can be disposed within a second plurality of die pockets 1314b, formed at least in part by the placement of the first plurality of dies 1306a. The second plurality of dies 1306b can be disposed onto the second plurality of conductive features 1309b, which had previously been covered by the temporary bumpers 1310 (shown in FIG. 13B). The manner in which the second plurality of dies 1306b are disposed onto the substrate 1304 can be similar to how the first plurality of dies 1306a had been disposed onto the substrate 1304: the die conductive features 1318 are configured to be directly bonded to the conductive features 1309 (particularly the second plurality of conductive features 1309b) of the microelectronic structure 1302 without any intervening adhesive, and die substrates 1316 (particularly insulating materials surrounding the die conductive features 1318) are configured to be directly bonded to the substrate 1304 of the microelectronic structure 1302 without any intervening adhesive.

In the illustrated embodiment of FIG. 13D, the die thickness 1317b of the second plurality of dies 1306b is greater than the die thickness 1317a of the first plurality of dies 1306a. This additional thickness effectively serves as a bumper that can constrain the placement of a third plurality of dies 1306c (shown in FIG. 13E). The gaps between neighboring dies 1306b form a third plurality of die pockets 1314c, configured to constrain a third plurality of dies 1306c. Effectively, the additional thickness of the second plurality of dies 1306b serves as bumpers that reduce the likelihood that a misplaced die from among the third plurality of dies 1306c will interfere with the placement of any neighboring dies.

It will be understood that the second plurality of dies 1306b can be thicker than the first plurality of dies 1306a, as shown in FIG. 13D. It will also be understood that the first plurality of dies 1306a can have the same thickness-when being disposed onto the substrate 1304—as the second plurality of dies 1306b, but then the first plurality of dies 1306a can be thinned (e.g., by filling gaps with a temporary filler and grinding or polishing) before the second plurality of dies 1306b are disposed onto the substrate 1304. It will also be understood that the second plurality of dies 1306b can have a thickness less than that of the first plurality of dies 1306a if a third layer of dies is instead to be added over the second plurality of dies 1306b. The common feature in all of these scenarios is that-before the third plurality of dies 1306c are placed—a third plurality of die pockets 1314c are formed into which the third plurality of dies 1306c can be disposed.

FIG. 13E depicts another bonded structure 1300c, comprising a microelectronic structure 1302 on which a first and second plurality of dies 1306a, 1306b have been disposed, and a third plurality of dies 1306c disposed onto the first plurality of dies 1306a. The third plurality of dies 1306c can be disposed within a third plurality of die pockets 1314c. formed at least in part by the difference in thickness between the first and second pluralities of dies 1306a, 1306b. The third plurality of dies 1306c can be disposed onto the first plurality of dies 1306a. The surface of the first plurality of dies 1306a to which the third plurality of dies 1306c are disposed can have conductive features (not shown) (e.g., traces, conductive pads, or through-substrate vias (TSVs)) which are configured to be bonded to the die conductive features 1318 of the third plurality of dies 1306c.

In FIG. 13E, the total thickness of the third plurality of dies 1306c and the thickness of the first plurality of dies 1306a is greater than the die thickness 1317b of the second plurality of dies 1306b. This additional thickness can effectively serve as a bumper that can constrain the placement of a fourth plurality of dies 1306d (shown in FIG. 13F). The gaps between neighboring dies 1306c form a fourth plurality of die pockets 1314d, configured to constrain a fourth plurality of dies 1306d. Effectively, the additional thickness of the third plurality of dies 1306c serves as bumpers that reduce the likelihood that a misplaced die from among the fourth plurality of dies 1306d will interfere with the placement of any neighboring dies.

FIG. 13F depicts another bonded structure 1300d, comprising a microelectronic structure 1302 on which a first and second plurality of dies 1306a, 1306b have been disposed; a third plurality of dies 1306c disposed onto the first plurality of dies 1306a; and a fourth plurality dies 1306d disposed onto the second plurality of dies 1306b. The fourth plurality of dies 1306d can be disposed within a fourth plurality of die pockets 1314d, formed at least in part by the difference in thickness between the stacked first and third pluralities of dies 1306a, 1306c and the second plurality of dies 1306b. The fourth plurality of dies 1306d can be disposed onto the second plurality of dies 1306b. The surface of the second plurality of dies 1306b to which the fourth plurality of dies 1306d are disposed can have conductive features (not shown) (e.g., traces, conductive pads, or through-substrate vias (TSVs)) which are configured to be bonded to the die conductive features 1318 of the fourth plurality of dies 1306d.

In FIG. 13F, the total thickness of the stacked fourth and second plurality of dies 1306d, 1306b is greater than the total thickness of the stacked third and first plurality of dies 1306c. 1306a. This additional thickness can effectively serve as a bumper that can constrain the placement of a fifth plurality of dies (not shown). Additional pluralities of dies can continue to be stacked in a similar manner (e.g., a fifth plurality of dies can be disposed onto the third plurality of dies 1306c; a sixth plurality of dies can be disposed onto the fourth plurality of dies 1306d; and so on). It will be understood that, once the final plurality of dies have been disposed onto the bonded structure, a difference in thickness between adjacent stacks of dies may not exist. For example, if only the bonded structure 1300b (shown in FIG. 13D) was desired—with first and second pluralities of dies 1306a, 1306b, but without the third and fourth pluralities of dies 1306c, 1306d—then the die thickness 1317b of the second plurality of dies 1306b could be the same as the die thickness 1317a of the first plurality of dies 1306a. In other words, if no additional dies will be disposed onto the bonded structure, an additional die pocket (e.g., the third plurality of die pockets 1314c, shown in FIG. 13D) can be omitted. The bonded structure 1300d of FIG. 13F can be subsequently singulated.

FIG. 13G depicts a schematic plan view of a bonded structure 1300e. according to some embodiments. The illustrated bonded structure 1300e includes a substrate 1304 and multiple pluralities of dies 1306a, 1306b bonded to the substrate 1304. A first plurality of dies 1306a are shown bonded to a first plurality of bonding regions on the substrate 1304, and a second plurality of dies 1306b are shown bonded to a second plurality of bonding regions on the substrate 1304. In the illustrated embodiment, the first and second pluralities of dies 1306a, 1306b alternate with each other in two dimensions, such as on a grid in a checkerboard pattern.

It will be understood by a skilled artisan that the bonded structure 1300e, shown in FIG. 13G, is analogous to bonded structure 1300b, shown in FIG. 13D, and bonded structure 1400b, shown in FIG. 14C, insofar as each bonded structure 1300b, 1300e, 1400b shows a first plurality of dies 1306a, 1406a occupying alternating positions on a substrate 1304, 1404 relative to a second plurality of dies 1306b, 1406b. However, whereas FIGS. 13D and 14C illustrate the alternation of dies in only one dimension, FIG. 13G is a schematic plan view showing alternations in two dimensions, e.g., two orthogonal dimensions. It will also be understood by a skilled artisan that the first plurality of dies 1306a are bonded to the substrate 1304 before the second plurality of dies 1306b are bonded to the substrate 1304. This means the first plurality of dies 1306a can act as bumpers constraining the placement of each of the second plurality of dies 1306b.

In some embodiments analogous to the bonded structure 1300b shown in FIG. 13D, the second plurality of bonding regions can be covered by a temporary bumper while the first plurality of dies 1306a are being placed on the substrate 1304, and the second plurality of dies 1306b can be placed on the substrate 1304 after the temporary bumper is removed. In other embodiments analogous to the bonded structure 1400b shown in FIG. 14C, the first plurality of bonding regions can be recessed relative to the second plurality of bonding regions; the first plurality of dies 1306a can be bonded to the recessed bonding regions with the recesses acting as bumpers constraining the placement of the first plurality of dies 1306a; then the second plurality of dies 1306b can be bonded to the second plurality of bonding regions, with the first plurality of dies 1306a acting as bumpers constraining the placement of each of the second plurality of dies 1306b.

In some embodiments, both the first plurality of dies 1306a and the second plurality of dies 1306b are directly bonded to the substrate 1304, as explained above. In other embodiments, the second plurality of dies 1306b can be flip-chip bonded. In such embodiments, the first plurality of dies 1306a are directly bonded to the substrate 1304, then the second plurality of dies 1306b can be flip-chip bonded on the substrate 1304 between the first plurality of dies 1306a. The flip-chip bonding can use conventional methods, for example, using adhesives.

Skilled artisans will understand that FIG. 13G is a schematic. While each of the first dies 1306a are shown to have the same shape and size as the second dies 1306b. some embodiments are not so limited. For example, in some embodiments, the first dies 1306a can have a different shape and/or size compared to the second dies 1306b. In other embodiments, there can be variety in size and/or shape among the first dies 1306a and/or variety in size and/or shape among the second dies 1306b. While the first and second pluralities of dies 1306a, 1306b are shown in a square grid, some embodiments are not so limited. In some embodiments, the dies 1306a, 1306b are arranged in a different pattern. And while first dies 1306a are only shown adjacent to second dies 1306b and second dies 1306b are only shown adjacent to first dies 1306a, some embodiments are not so limited. For example, two or more dies from among the first plurality of dies 1306a can be adjacent to one another, and/or two or more dies from among the second plurality of dies 1306b can be adjacent to one another.

FIGS. 14A-14E depict one method of forming a sixth type of bonded structure (e.g., bonded structures 1400a, 1400b, 1400c, 1400d of FIGS. 14B-14E). The method depicted in FIGS. 14A-14E and described herein is similar to the method depicted in FIGS. 13A-13F, and can be considered a hybrid process of FIGS. 13A-13F with FIGS. 8A-8J: it is another example of how to dispose a first plurality of dies (e.g., 1406a in FIG. 14B) into a first plurality of die pockets (e.g., 1414a in FIG. 14A), then dispose a second plurality of dies (e.g., 1406b in FIG. 14C) into a second plurality of die pockets (e.g., 1414b in FIG. 14B), wherein the second plurality of die pockets (e.g., 1414b) is at least partially formed by the first plurality of dies (e.g., 1406a). The bonded structure 1400d formed by the method depicted in FIGS. 14A-14E is one example of a bonded structure that utilizes non-recessed bonding surfaces 1415b to constrain the placement of a first plurality of dies 1406a onto a first plurality of conductive features 1409a that are at least partially embedded in a recessed bonding surface 1415a, then utilizes the first plurality of dies 1406a to constrain the placement of a second plurality of dies 1406b onto a second plurality of conductive features 1409b that are at least partially embedded in the non-recessed bonding surfaces 1415b, then utilizes the second plurality of dies 1406b to constrain the placement of a third plurality of dies 1406c on top of the first plurality of dies 1406a, then utilizes the third plurality of dies 1406c to constrain the placement of a fourth plurality of dies 1406d on top of the second plurality of dies 1406b.

It will be understood that before any dies (e.g., 1406a, 1406b, 1406c, 1406d) are disposed (e.g., direct bonded or hybrid bonded, without an intervening adhesive) onto another feature (e.g., to the substrate 1404 or another die 1406a, 1406b), the bonding interface can be prepared for direct bonding, as described herein.

FIG. 14A depicts a microelectronic structure 1402 comprising a substrate 1404, including a bulk semiconductor region 1404a and a bonding layer 1404b, and bumpers 1410. FIG. 14A is similar to FIG. 8F. For example, substrate 1404 can be similar to the substrate 804 of FIG. 8F. Conductive features 1409a, 1409b can be similar to other conductive features described herein (e.g., 809 of FIG. 8A, 909 of FIG. 9A, 1109 of FIG. 11A, 1209 of FIG. 12A, and 1309a and 1309b of FIG. 13A). The recessed (e.g., etched) bonding surface 1415a can be similar (e.g., in material, dimensions, and function) to the recessed bonding surface 815 of FIG. 8F. The non-recessed surfaces 1415b effectively serve as bumpers 1410, with the difference in depth between the recessed surfaces 1415a and the non-recessed surfaces 1415b defining a bumper height 1412. The gaps between neighboring non-recessed surfaces 1415b form a first plurality of die pockets 1414a configured to constrain the first plurality of dies 1406a, which is similar to how die pockets 814 are configured to constrain the plurality of dies 806 in FIG. 8G-8H.

FIGS. 14A and 8F have some differences. FIG. 14A depicts a first plurality of conductive features 1409a and a second plurality of conductive features 1409b. The first plurality of conductive features 1409a is similar to the conductive features 809 of FIG. 8F, and are at least partially embedded in a plurality of recessed bonding surfaces 1415a. The first plurality of conductive features 1409a is configured to be bonded to a first plurality of dies 1406a (shown in FIG. 14B). The second plurality of conductive features 1409b is depicted in FIG. 14A as being at least partially embedded in a plurality of non-recessed bonding surfaces 1415b. The second plurality of conductive features 1409b is configured to be bonded to a second plurality of dies 1406b (shown in FIG. 14C), after the first plurality of dies 1406a are disposed onto bonded to the first plurality of conductive features 1409a (shown in FIG. 14B).

FIG. 14B depicts a bonded structure 1400a, comprising the microelectronic structure 1402 of FIG. 14A on which a first plurality of dies 1406a have been disposed. FIG. 14B is similar to FIG. 8H, in that they both depict dies (dies 806 in FIG. 8H, and a first plurality of dies 1406a in FIG. 14B) being disposed onto the microelectronic structure (1402 in FIG. 14B, 802 in FIG. 8H), in similar ways. The bumper height 1412 is less than the thickness of the first plurality of dies 1406a. This additional thickness of the first plurality of dies 1406a (i.e., the top of the die 1406a that extends above the non-recessed bonding surface 1415b) effectively serves as a bumper that will constrain the placement of the second plurality of dies 1406b (shown in FIG. 14C). The gaps between neighboring dies 1406a form a second plurality of die pockets 1414b, configured to constrain a second plurality of dies 1406b. Effectively, the first plurality of dies 1406a serves as bumpers that reduce the likelihood that a misplaced die from among the second plurality of dies 1406b will interfere with the placement of any neighboring dies.

FIG. 14C depicts another bonded structure 1400b, comprising the bonded structure 1400a of FIG. 14B on which the second plurality of dies 1406b has been disposed. The second plurality of dies 1406b can be disposed within the second plurality of die pockets 1414b, formed at least in part by the placement of the first plurality of dies 1406a. The second plurality of dies 1406b can be disposed onto the second plurality of conductive features 1409b, which are at least partially embedded in the non-recessed bonding surface 1415b of substrate 1404. The manner in which the second plurality of dies 1406b is disposed onto the substrate 1404 is similar to how the first plurality of dies 1406a had been disposed onto the substrate 1404: die conductive features (not shown) are configured to be directly bonded to the conductive features 1409b of the microelectronic structure 1402 without any intervening adhesive, and die substrates (and particularly a bonding layer of the die substrates, not separately labeled) are configured to be directly bonded to the substrate 1404 of the microelectronic structure 1402 without any intervening adhesive.

The thickness of the second plurality of dies 1406b is such that the second plurality of dies 1406b extends above the first plurality of dies 1406a by at least a bumper height. This additional thickness of the second plurality of dies 1406b (i.e., the top of the die 1406b that extends above the first plurality of dies 1406a) effectively serves as a bumper that can constrain the placement of the third plurality of dies 1406c (shown in FIG. 14D). The gaps between neighboring second dies 1406b form a third plurality of die pockets 1414c, configured to constrain a third plurality of dies 1406c. Effectively, the second plurality of dies 1406b serves as bumpers that reduce the likelihood that a misplaced die from among the third plurality of dies 1406c will interfere with the placement of any neighboring dies.

FIG. 14D depicts a bonded structure 1400c, comprising the bonded structure 1400b of FIG. 14C on which the third plurality of dies 1406c has been disposed onto the first plurality of dies 1406a. The third plurality of dies 1406c can be disposed within a third plurality of die pockets 1414c, formed at least in part by the placement of the second plurality of dies 1406b. The surface of the first plurality of dies 1406a to which the third plurality of dies 1406c are disposed can have conductive features (not shown) (e.g., traces, conductive pads, or through-substrate vias (TSVs)) which are configured to be bonded to the die conductive features (not shown) of the third plurality of dies 1406c.

The thickness of the third plurality of dies 1406c is such that the third plurality of dies 1406c extends above the second plurality of dies 1406b. This additional thickness of the third plurality of dies 1406c (i.e., the top of the die 1406c that extends above the second plurality of dies 1406b) effectively serves as a bumper that can constrain the placement of a fourth plurality of dies 1406d (shown in FIG. 14E). The gaps between neighboring third dies 1406c form a fourth plurality of die pockets 1414d, configured to constrain the fourth plurality of dies 1406d. Effectively, the third plurality of dies 1406c serves as bumpers that reduce the likelihood that a misplaced die from among the fourth plurality of dies 1406d will interfere with the placement of any neighboring dies.

FIG. 14E depicts a bonded structure 1400d, comprising the bonded structure 1400c of FIG. 14D on which the fourth plurality of dies 1406d has been disposed onto the second plurality of dies 1406b. The fourth plurality of dies 1406d can be disposed within the fourth plurality of die pockets 1414d, formed at least in part by the placement of the third plurality of dies 1406c. The fourth plurality of dies 1406d can be disposed onto the second plurality of dies 1306b. The surface of the second plurality of dies 1406b to which the fourth plurality of dies 1406d are disposed can have conductive features (not shown) (e.g., traces, conductive pads, or through-substrate vias (TSVs)) which are configured to be bonded to the die conductive features (not shown) of the fourth plurality of dies 1406d.

The thickness of the fourth plurality of dies 1406d can be such that the fourth plurality of dies 1406d extends above the third plurality of dies 1406c by at least a bumper height. This additional thickness of the fourth plurality of dies 1406d (i.e., the top of the die 1406d that extends above the third plurality of dies 1406c) can effectively serve as a bumper that can constrain the placement of a fifth plurality of dies (not shown). Additional pluralities of dies can continue to be stacked in a similar manner (e.g., a fifth plurality of dies can be disposed onto the third plurality of dies 1406c; a sixth plurality of dies can be disposed onto the fourth plurality of dies 1406d; and so on). It will be understood that, once the final plurality of dies have been disposed onto the bonded structure, a difference in thickness between adjacent stacks of dies could be omitted. For example, if only the bonded structure 1400b (shown in FIG. 14C) was desired—with first and second pluralities of dies 1406a, 1406b, but without the third and fourth pluralities of dies 1406c, 1406d—then the second plurality of dies 1406b could be roughly coplanar with the first plurality of dies 1406a. In other words, if no additional dies will be disposed onto the bonded structure, an additional die pocket (e.g. the third plurality of die pockets 1414c, shown in FIG. 14C) could be omitted. The bonded structure 1400d of FIG. 14E can be subsequently singulated.

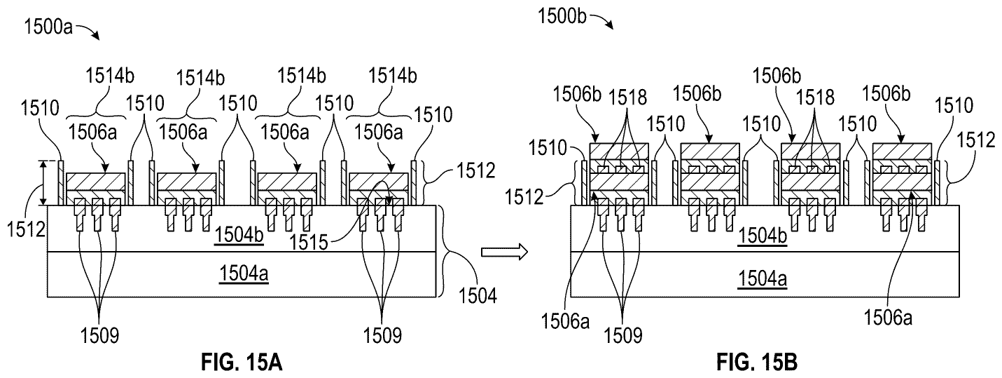

FIGS. 15A-15B depict one method of forming a seventh type of bonded structure (e.g., bonded structures 1500a, 1500b of FIGS. 15A-15B). The method depicted in FIGS. 15A-15B and described herein is similar to the method depicted in FIGS. 11E-11H: it is another example of a bonded structure that comprises at least one bumper 1510 that is disposed on the substrate 1504. In the method depicted in FIGS. 15A-15B and described herein, bumpers 1510 have a bumper height 1512 that is greater than a thickness of a first plurality of dies 1506a and can subsequently also serve as bumpers that confine the placement of a second plurality of dies 1506b disposed onto the first plurality of dies 1506a.

It will be understood that before any dies (e.g., 1506a, 1506b) are disposed (e.g., direct bonded or hybrid bonded, without intervening adhesive) onto another feature (e.g., to the substrate 1504 or another die 1506a), the bonding interface can be prepared for direct bonding, as described herein.

FIG. 15A depicts a bonded structure 1500a that comprises a substrate 1504, including a bulk semiconductor region 1504a and a bonding layer 1504b, bumpers 1510, and a first plurality of dies 1506a disposed on the substrate 1504. FIG. 15A is similar to FIG. 11E. For example, substrate 1504 can be similar to the substrate 1104 of FIG. 11E. Conductive features 1509 can be similar to other conductive features described herein (e.g., 809 of FIG. 8A, 909 of FIG. 9A, 1109 of FIG. 11A, 1209 of FIG. 12A, 1309 of FIG. 13A, and 1409 of FIG. 14A). The bumpers 1510 can be similar (e.g., in material and function—though not in dimensions) to the bumpers 1110 of FIG. 11E. And a first plurality of dies 1506a are disposed onto the substrate 1504 such that the first plurality of dies 1506a are bonded to conductive features 1509 and such that the first plurality of dies 1506a are constrained by bumpers 1510. The first plurality of dies 1506a, like other dies described herein that are meant to have additional dies stacked thereover, can have through substrate vias (TSVs) connecting to backside conductive features (not shown).

The bumpers 1510 of FIG. 15A have a greater bumper height 1512 than the bumper height 1112 of the bumpers 1110 of FIG. 11E. Specifically, the bumper height 1512 of the bumpers 1510 in FIG. 15A is greater than the thickness of the first plurality of dies 1506a. The bumpers 1510 extend above the first plurality of dies 1506a by at least the bumper height of other embodiments described herein (e.g., bumper height 812, 912, and 1112). In some embodiments, bumpers 1510 extend above the first plurality of dies 1506a by about or at least 20 nm, 25 nm, 50 nm, 75 nm, 100 nm, 200 nm, 300 nm, 400 nm, 500 nm, 600 nm, 700 nm, 750 nm, 800 nm, 900 nm, 1 micron, 2 microns, 3 microns, 4 microns, 5 microns, 10 microns, 15 microns, or more or any interval therebetween. This additional thickness of the bumper 1510 (i.e., the top of the bumper 1510 that extends above the first plurality of dies 1506a) effectively serves as a bumper that can also constrain the placement of the second plurality of dies 1506b (shown in FIG. 15B). The gaps between neighboring bumpers 1510 form a second plurality of die pockets 1514b, configured to constrain a second plurality of dies 1506b, which reduces the likelihood that a misplaced or slipped die from among the second plurality of dies 1506b will interfere with the placement of any neighboring dies.

FIG. 15B depicts a bonded structure 1500b that comprises the bonded structure 1500a of FIG. 15A, with a second plurality of dies 1506b disposed on the first plurality of dies 1506a. The second plurality of dies 1506b can be disposed onto the first plurality of dies 1506a. The backside surface of the first plurality of dies 1506a to which the second plurality of dies 1506b are disposed can have conductive features (not shown) (e.g., traces, conductive pads, or through-substrate vias (TSVs)) which are configured to be bonded to the die conductive features 1518 of the second plurality of dies 1506b.

The thickness of the second plurality of dies 1506b depicted in FIG. 15B is such that the bumpers 1510 do not extend above the second plurality of dies 1506b. It will be understood, however, that the bumpers 1510 can be configured to have a height sufficient to extend above the second plurality of dies 1506b, for example, to serve as a bumper for a third plurality of dies (not shown) to be disposed onto the second plurality of dies 1506b. The various bonded or stacked bonded structures of this disclosure may be encapsulated with a mold layer prior to singulation. In other embodiments, the singulated dies may be encapsulated with a mold before subsequent processing. In some embodiments, the stacked structure may comprise for example, an interposer. The interposer can have a larger die (for example, a microprocessor or a graphics processor), and supporting dies can be disposed lateral to the larger die. The supporting dies may comprise memory dies, MEMS components, optical components, or passive elements, among other examples. In some embodiments, the supporting dies may be stacked. In one embodiment, the supporting dies may be stacked over the larger die.

In one aspect, a bonded structure includes a substrate that includes a bonding surface. At least one bumper extends above the bonding surface of the substrate. At least one die is directly bonded to the bonding surface adjacent the bumper.

In some embodiments, the at least one die is hybrid bonded to the bonding surface adjacent the bumper. In some embodiments, the at least one die has a thickness greater than a bumper height of the at least one bumper. In some embodiments, the bumper height is between about 25 nm and 10 microns. In some embodiments, the at least one bumper surrounds the at least one die and defines a die pocket having a pocket width greater than a width of the at least one die by between about 2 microns and 7 microns. In some embodiments, the at least one bumper includes a single continuous bumper element surrounding the die pocket. In some embodiments, the at least one bumper includes a plurality of discontinuous bumper elements surrounding the die pocket. In some embodiments, the plurality of discontinuous bumper elements is located beside a plurality of edges of the at least one die. In some embodiments, the plurality of discontinuous bumper elements frames a plurality of corners of the at least one die. In some embodiments, the at least one bumper is integrally formed with the substrate. In some embodiments, the at least one bumper includes the same material and is monolithic with a dielectric material of the substrate at the bonding surface. In some embodiments, the at least one bumper includes a material different from a material of the substrate at the bonding surface. In some embodiments, the at least one bumper includes photoresist. In some embodiments, the substrate comprises a semiconductor wafer. In some embodiments, the substrate includes an integrated circuit die. In some embodiments, the at least one bumper comprises an electrically conductive material electrically connected to the substrate. In some embodiments, a bumper height is between about 100 nm and 750 nm.

In another aspect, a microelectronic structure includes a substrate that includes a bonding surface. The bonding surface includes a plurality of bonding regions for hybrid bonding. At least one bumper extends above the bonding surface of the substrate. The at least one bumper separates at least two of the plurality of bonding regions.

In some embodiments, a bumper height of the at least one bumper is between about 25 nm and 10 microns. In some embodiments, at least one of the plurality of bonding regions occupies a substantially differently shaped and/or sized footprint on the substrate than at least one other of the plurality of bonding regions. In some embodiments, the at least one bumper is integrally formed with the substrate. In some embodiments, the at least one bumper is made of the same material and monolithic with a material of the substrate at the bonding surface. In some embodiments, the at least one bumper is a different material from a dielectric material of the substrate at the bonding surface and is fixed to the substrate. In some embodiments, the at least one bumper comprises photoresist.

In another aspect, a method of hybrid bonding includes providing a substrate that includes a plurality of bonding surfaces having bonding regions. The method also includes providing at least one bumper extending above the plurality of bonding surfaces of the substrate. The at least one bumper separates the bonding regions. The method also includes hybrid bonding a plurality of dies on the plurality of bonding surfaces.

In some embodiments, a bumper height of the at least one bumper is between about 25 nm and 10 microns. In some embodiments, the at least one bumper separates each of the plurality of dies from one another. In some embodiments, each of the bonding regions corresponds to a device of a package formed from the substrate, and the at least one bumper surrounds more than one of the plurality of dies on the device. In some embodiments, the method further includes after hybrid bonding the plurality of dies on the bonding regions, removing at least one of the at least one bumper. In some embodiments, the method further includes, after removing at least one bumper separating a first plurality of dies, providing at least one intermediate bonding surface on the substrate between the first plurality of dies, and hybrid bonding at least one intermediate die on the at least one intermediate bonding surface. In some embodiments, the at least one intermediate die has a thickness greater than thicknesses of the first plurality of dies adjacent to the intermediate dies. In some embodiments, the method further includes, after hybrid bonding the at least one intermediate die on the at least one intermediate bonding surface, hybrid bonding at least one upper die on an exposed surface of at least one of the first plurality of dies adjacent to at least one intermediate die. In some embodiments, the substrate includes a wafer, and the method also includes singulating the wafer into devices after hybrid bonding, where each of the devices corresponding to one of the bonding regions. In some embodiments, each of the bonding regions includes two or more of the plurality of dies surrounded by the at least one bumper. In some embodiments, providing the at least one bumper includes etching the substrate. In some embodiments, providing the at least one bumper includes depositing the at least one bumper on the substrate. In some embodiments, depositing the at least one bumper on the substrate includes 3D-printing the at least one bumper on the substrate. In some embodiments, the at least one bumper includes an oxide. In some embodiments, the at least one bumper includes an electrically conductive material electrically connected to the substrate. In some embodiments, a bumper height of the at least one bumper is between about 100 nm and 750 nm.

In another aspect, a microelectronic structure is provided. The microelectronic structure includes a substrate that includes an upper surface for hybrid bonding and a recessed bonding surface for hybrid bonding. The recessed bonding surface is below the upper surface of the substrate.

In another aspect, a bonded structure is provided. The bonded structure includes a substrate that includes an upper surface, a recessed bonding surface below the upper surface of the substrate, and at least one die directly bonded to the recessed bonding surface.

In some embodiments, the upper surface of the substrate is an upper bonding surface, and at least one additional die is directly bonded to the upper bonding surface. In some embodiments, a top exposed surface of the at least one die bonded to the upper bonding surface is above a top exposed surface of the at least one die bonded to the recessed bonding surface. Additionally, a top exposed surface of at least one die bonded to the recessed bonding surface is a top bonding surface. And furthermore, at least one additional die is directly bonded to the top bonding surface.

In another aspect, a method of forming a bonded structure is provided. The method includes providing a substrate that includes a first plurality of bonding regions in alternating regions compared to a second plurality of bonding regions. The bonding regions of the second plurality of bonding regions are between adjacent bonding regions of the first plurality of bonding regions. The method also includes hybrid bonding a first plurality of dies on the first plurality of bonding regions of the substrate. The method also includes, after hybrid bonding the first plurality of dies, bonding a second plurality of dies on the second plurality of bonding regions of the substrate.

In some embodiments, the first plurality of bonding regions and the second plurality of bonding regions alternate in two dimensions of the substrate. In some embodiments, the second plurality of dies are flip-chip bonded to the substrate. In some embodiments, the second plurality of dies are hybrid bonded on the second plurality of bonding regions of the substrate. In some embodiments, the first plurality of bonding regions are recessed by a bumper height relative to the second plurality of bonding regions. In some embodiments, the bumper height is between about 25 nm and 10 microns. In some embodiments, exposed surfaces of the second plurality of dies extend above exposed surfaces of the first plurality of dies by a bumper height, and the method further includes bonding a third plurality of dies on the exposed surfaces of the first plurality of dies. In some embodiments, exposed surfaces of the third plurality of dies extend above exposed surfaces of the second plurality of dies, and the method further includes bonding a fourth plurality of dies on the exposed surfaces of the second plurality of dies. In some embodiments, the substate is substantially planarized, and before hybrid bonding the first plurality of dies on the first plurality of bonding regions, the method also includes disposing a temporary bumper over the second plurality of bonding regions. The method also includes, after hybrid bonding the first plurality of dies but before bonding the second plurality of dies on the second plurality of bonding regions, removing the temporary bumpers. In some embodiments, a thickness of the first plurality of dies is less by a bumper height compared to a thickness of the second plurality of dies. The method further includes bonding a third plurality of dies on exposed surfaces of the first plurality of dies. In some embodiments, exposed surfaces of the third plurality of dies extend above exposed surfaces of the second plurality of dies. The method also includes bonding a fourth plurality of dies on the exposed surfaces of the second plurality of dies.

In another aspect, a bonded structure is provided. The bonded structure includes a substrate that has a surface. The bonded structure also includes a plurality of discontinuous bumpers extending above the surface of the substrate. At least one die is attached to the surface within a region surrounded by the discontinuous bumpers. The at least one die has a thickness greater than a bumper height of at least one of the plurality of discontinuous bumpers.

In some embodiments, the at least one die is attached to the surface with solder. In some embodiments, bumper heights of the plurality of discontinuous bumpers are between about 25 nm and 10 microns.

Unless the context clearly requires otherwise, throughout the description and the claims, the words “comprise,” “comprising.” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above.” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might.” “may.” “e.g.,” “for example.” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. A bonded structure comprising:
a substrate that includes a bonding surface;
at least one bumper extending above the bonding surface of the substrate; and
at least one die directly bonded to the bonding surface adjacent the bumper.

2. The bonded structure of claim 1, wherein the at least one die is hybrid bonded to the bonding surface adjacent the bumper.

3. The bonded structure of claim 1, wherein the at least one die has a thickness greater than a bumper height of the at least one bumper, and wherein the bumper height is between about 25 nm and 10 microns.

4. (canceled)

5. The bonded structure of claim 1, wherein the at least one bumper surrounds the at least one die and defines a die pocket having a pocket width greater than a width of the at least one die by between about 2 microns and 7 microns.

6. (canceled)

7. The bonded structure of claim 5, wherein the at least one bumper comprises a plurality of discontinuous bumper elements surrounding the die pocket.

8. (canceled)

9. (canceled)

10. (canceled)

11. The bonded structure of claim 1, wherein the at least one bumper comprises the same material and is monolithic with a dielectric material of the substrate at the bonding surface.

12. The bonded structure of claim 1, wherein the at least one bumper comprises a material different from a material of the substrate at the bonding surface.

13. (canceled)

14. The bonded structure of claim 1, wherein the substrate comprises a semiconductor wafer.

15. The bonded structure of claim 1, wherein the substrate comprises an integrated circuit die.

16. (canceled)

17. (canceled)

18. A microelectronic structure comprising:
a substrate that includes a bonding surface, the bonding surface including a plurality of bonding regions for hybrid bonding; and
at least one bumper extending above the bonding surface of the substrate, the at least one bumper separating at least two of the plurality of bonding regions.

19. The microelectronic structure of claim 18, wherein a bumper height of the at least one bumper is between about 25 nm and 10 microns.

20. The microelectronic structure of claim 18, wherein at least one of the plurality of bonding regions occupies a substantially differently shaped and/or sized footprint on the substrate than at least one other of the plurality of bonding regions.

21. (canceled)

22. The microelectronic structure of claim 18, wherein the at least one bumper is made of the same material and monolithic with a material of the substrate at the bonding surface.

23. The microelectronic structure of claim 18, wherein the at least one bumper is a different material from a dielectric material of the substrate at the bonding surface and is fixed to the substrate.

24. (canceled)

25. A method of hybrid bonding, the method comprising:
providing a substrate that includes a plurality of bonding surfaces having bonding regions;
providing at least one bumper extending above the plurality of bonding surfaces of the substrate, the at least one bumper separating the bonding regions; and
hybrid bonding a plurality of dies on the plurality of bonding surfaces.

26. The method of claim 25, wherein a bumper height of the at least one bumper is between about 25 nm and 10 microns.

27. The method of claim 25, wherein the at least one bumper separates each of the plurality of dies from one another.

28. (canceled)

29. (canceled)

30. (canceled)

31. (canceled)

32. (canceled)

33. The method of claim 25, wherein the substrate comprises a wafer, and the method further comprising singulating the wafer into devices after hybrid bonding, each of the devices corresponding to one of the bonding regions.

34. (canceled)

35. The method of claim 25, wherein providing the at least one bumper comprises etching the substrate.

36. The method of claim 25, wherein providing the at least one bumper comprises depositing the at least one bumper on the substrate.

37. (canceled)

38. (canceled)

39. (canceled)

40. (canceled)

41-58. (canceled)
